(19) United States
(12) Patent Application Publication
(10) Pub. No.: US 2024/0381538 A1
(43) Pub. Date: Nov. 14, 2024

(54) Manufacturing a Component Carrier by a Nano Imprint Lithography Process

(71) Applicant: AT&S Austria Technologie & Systemtechnik, Leoben (AT)

(72) Inventors: Heinrich TRISCHLER, Eggersdorf (AT); Erich PREINER, St. Michael in Oberstreiermark (AT); Marie SCALBERT, Leoben (AT)

(21) Appl. No.: 18/692,075

(22) PCT Filed: Oct. 29, 2021
(86) PCT No.: PCT/IB2021/000939

§ 371 Date: Mar. 14, 2024

(51) Int. Cl. H05K 3/00; G03F 7/00; H05K 1/11; H05K 1/18; H05K 3/40

(52) U.S. Cl. CPC H05K 3/0044; G03F 7/0002; H05K 1/115; H05K 1/181; H05K 3/007; H05K 3/0076; H05K 3/4061; H05K 2201/09545; H05K 2201/09827; H05K 2203/0582

(57) ABSTRACT

The present disclosure relates to a method of manufacturing a layer structure for a component carrier. According to the method, a carrier layer is provided. An imprint resist layer is added onto the carrier layer and predefined structures forming at least one recess are stamped into the imprint resist layer by a predefined stamp. The recess defines a filling structure in or on the carrier layer. In the filling structure at least one of an electrically insulating material and an electrically conductive material is filled.

### CROSS-REFERENCE TO RELATED APPLICATIONS

This application is the U.S. national phase of International Application No. PCT/IB2021/0000939 filed Oct. 29, 2021, the disclosure of which is hereby incorporated herein by reference.

### TECHNICAL FIELD

The disclosure relates to a method of manufacturing a layer structure for a component carrier by a nano imprint lithography (NIL) process. Furthermore, the disclosure relates to respective component carrier comprising the layer structure manufactured by the nano imprint lithography process.

### TECHNOLOGICAL BACKGROUND

A component carrier, such as a printed circuit board (PCB) or a substrate, mechanically supports and electrically connects active and passive electronic components. Electronic components are mounted on the component carrier and are interconnected to form a working circuit or electronic assembly.

During the manufacturing of chip embedded PCBs the embedded components need to be connected to the copper structures. Usually this connection is done after the chip embedding process and after a pressing process by which the laminated layers of the component of the component carrier are pressed together. There are different production routes to connect the components after the pressing process. One method is to perform the embedding process with a temporary protection during the embedding and pressing process of the component carrier. After the pressing and embedding process, the temporary protection is removed and the chip pads are visible on the surface of the component carrier. The component pads can be contacted by e.g. Titanium and Copper sputtering process followed by copper process or directly by a copper plating process.

Currently, fine line structures, such embedded electrically conductive line structures in the layers of the component carrier, are usually manufactured by a lithography and subsequent etching process. For example, a Laser Direct Imaging (LDI) technology can be applied in order to achieve fine line structures. However, LDI imaging pixel size can result in a variation of the laser beam size and therefore in a variation of fine line sizes. Non-cured photo resist needs to be removed after the LDI process (additional process steps are required). The development of the non-cured photo resist after UV-imaging process can be a challenge for fine lines structures, any residues leading to electrical opens open in the fine line structures.

However, when applying the LDI process, a plurality of manufacturing steps are necessary in order to proceed after the manufacturing of one layer structure of the component carrier with further manufacturing steps, such as the coupling of a component. For example, respective masks or other temporary layers have to be washed off in order to clean the manufactured layers.

Specifically, in mass production of component carriers, very precise and fast processes for manufacturing fine lines are required. Up to now, only LDI processes are used in mass production of component carriers. Hence, there may be a need for a faster manufacturing of precise and layer structures with fine lines for component carriers.

### SUMMARY

This need may be met by the subject matter according to the independent claims. Advantageous embodiments of the present disclosure are described by the dependent claims.

According to a first embodiment of a method of manufacturing a layer structure for a component carrier. According to the method, a carrier layer (e.g. an electrically conductive layer or an electrically insulating layer) is provided. An imprint resist layer is added onto the carrier layer. Predefined structures forming at least one recess are stamped into the imprint resist layer by a predefined stamp. The recess defines a filling structure in or on the carrier layer.

In the respective filling structure at least one of an electrically insulating material and an electrically conductive is filled.

According to a further embodiment of the present disclosure a component carrier having least one layer structure (in particular manufactured with the method as described above) with at least one carrier layer (e.g. an electrically conductive layer or an electrically insulating layer) is provided. The at least one layer structure comprises an imprint resist layer, wherein the imprint resist layer comprises predefined stamped structures being in contact with the at last one carrier layer, wherein the predefined stamped structures comprise at least one recess defining a filling structure in or on the carrier layer, which filling structure is filled by at least one of an electrically insulating material and an electrically conductive material.

### OVERVIEW OF EMBODIMENTS

In an exemplary embodiment, the carrier layer is an electrically conductive layer, wherein the filling structure forms electrically insulated patterns in the electrically conductive layer for defining borders of electrically conductive traces formed by the electrically conductive layer.

In the context of the present application, the term “component carrier” may particularly denote any support structure which is capable of accommodating electronic active or passive components thereon and/or therein for providing mechanical support and/or electrical connectivity. In other words, a component carrier may be configured as a mechanical and/or electronic carrier for active and passive components. In particular, a component carrier may be one of a printed circuit board, an organic interposer, and an IC (integrated circuit) substrate. A component carrier may also be a hybrid board combining different ones of the above-mentioned types of component carriers.

The component carrier comprises the stack of layer structures, e.g. at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure, if desired supported by thermal energy. The mentioned stack may provide a plate-shaped component carrier capable of providing a large mounting surface for further components and being nevertheless very thin and compact. The term “layer structure” may particularly denote a continuous layer, a patterned layer or a plurality of non-consecutive islands within a common plane. In the context of the present disclosure, the term “layer structure” may be a single layer or multilayer assembly.

The carrier layer may be an electrically conductive layer or an electrically insulating layer, i.e. a dielectric layer. The carrier layer may be arranged on an electrically insulating substrate, e.g. a comprising glass material. The carrier layer may also be arranged on a further exposed layer of a further layer stack, e.g. a premanufactured layer stack. Specifically, in an exemplary embodiment, the carrier layer is an exposed outer layer of an already premanufactured layer stack.

The electrically conductive layer defining the carrier layer may be for example a layer made of a conductive metal material, such as copper. The electrically conductive layer may be for example a conductive foil having a thickness of 1 μm to 10 μm (micrometer). The electrically conductive layer may be applied on a temporary carrier structure, a substrate (made e.g. of resin) or a further layer structure made of a stack of several electrically conductive and electrically insulating layers. The further layer structure may also be formed by the NIL manufacturing method according to the present disclosure.

The carrier layer may be formed be applied on a temporary carrier which may be removed at the end of the manufacturing process. However, alternatively, the carrier layer may be formed on a carrier which may form part of the component carrier, in which case the carrier is not removed from the imprint resist layer. Such a carrier may also be—in particular directly—connected to the imprint resist layer (i.e. may also be provided without release layer in between). A permanent carrier forming part of a component carrier according to an exemplary embodiment of the disclosure may be made preferably of glass. It is specifically preferred that such a component carrier with glass carrier is configured as interposer. Hence, in particular when glass is used as insulating layer or insulating carrier, it may be advantageous that an additive build-up with NIL is used for manufacturing an interposer. As interposers can be advantageously made with glass as insulating material, the carrier structure (or further build-up structure) can be advantageously used for a NIL process.

The imprint resist layer is added onto the carrier layer for example by dispensing coating or by spin coating. The imprint resist layer may be coated in the full area of the electrically conductive layer. This area can be part of the electrically conductive layer or the full electrically conductive layer. Hence, for example protrusions, which should be not coated with an e.g. electrically conductive material, may be protected by the imprint resist layer. In an exemplary embodiment, the imprint resist layer is added selectively on specific locations of the surface of the electrically conductive layer, such that specific other locations of the surface of the electrically conductive layer, such as vias, through holes or other functional locations, can be uncovered by the imprint resist layer also before the stamping step is conducted.

For example, an adhesion promoter layer or a barrier layer may be applied between the imprint resist layer and the electrically conductive layer. An adhesion promoter layer may be optional since the imprint resist layer may adhere without an additional adhesion promotor. The adhesion promoter layer comprises for example Silanes or Siloxanes and their compositions as well as metals as Tin, Zinc, Nickel, Aluminum, Copper and their mixtures or alloys. Mixtures may be a combination of silanes/siloxanes with metals, and alloy may refer to the mixture of metals. A barrier layer may be used to prevent (ion) migration. Thus, by preventing migration, the reliability of the component carrier may be increased.

The imprint resist layer may be an electrically insulating, dielectric layer configured for being deformable by a respective predefined stamp. Hence, the imprint resist layer is configured for being stamped in an imprinting step, in particular a Nanoimprint lithography (NIL) step. The NIL process is a method of fabricating nanometer scale patterns. The nanolithography process creates patterns by mechanical deformation of the imprint resist layer and subsequent processes. The imprint resist layer is typically a monomer or polymer formulation that is cured by heat or UV light during or after the imprinting. Adhesion between the resist and the stamp may be controlled to allow proper release.

By the stamp, the filling structure comprising a plurality of fine line recesses can be stamped in the imprint resist layer. The recesses in the imprint resist layer may comprise different depths, so that a customized and fine line filling structure and via structure can be printed. The recess and the filling structures are of different depth and/or different length in the imprint resist layer and/or the carrier layer.

The recesses define a location of the filling structures in or on the carrier layer. In a first embodiment (see e.g. FIGS. 2D and 2E), the recess provides a through hole through the imprint resist layer, so that through the through hole the carrier layer is reachable and so that the filling structure is formed and defined “on” the carrier layer. By an additive (e.g. plating) process, the through hole and recess, respectively can be filled with electrically conductive material (mSAP process (modified Semi Additive Process) or electrically insulating material.

In a second embodiment (see e.g. FIG. 1D, the recess defines a through hole through the imprint resist layer, so that through the recess the carrier layer is reachable. Next, in a subtractive process (e.g. etching), the carrier layer may be structured. Hence, the filling structure is formed and defined “in” the carrier layer. For example and optionally after removing the imprint resist layer, the filling structure can be filled with electrically conductive or insulating material.

The filling structure forms at least one electrically conductive sub-structure having a depth-to-diameter ratio of larger than 1, and in particular of larger than 1.5. In the context of the present application, the term “stamping a predefined (filling) structure in the imprint resist layer” may denote the process of imprinting or embossing a predefined surface pattern in the imprint resist layers. For instance, this may be accomplished by pressing a working mold (or working stamp) in the (in particular still) deformable imprint resist layer or by guiding a working mold along the (in particular still) deformable imprint resist layer. Such a working mold may have an inverse surface profile in comparison with the surface profile of the imprint resist layer being processed. During a development and manufacturing process, first a master mold may be manufactured, for example by gray scale lithography. Then the master mold may be replicated by stamping several times into a transparent silicone material or the like, and a master working mold may be generated. Finally, working molds may be made by copying the master working mold. The working molds may be used during mass production and imprinted on panel surface.

The recesses may be filled with electrically conductive material for forming the filling structure. The filling structure forms electrically conductive trace-type and/or via-type sub-structures, in particular form at least one electrically conductive trace-type sub-structure and at least one via-type sub-structure in the imprint resist layer. Hence, customized vias and fine line traces can be provided.

The stamp comprises a predefined negative pattern and therefore forms a type of mold which may be applied upon pressure and temperature on top the surface of the imprint resist layer. Thereby, desired patterns of recesses and protrusions are formed onto the imprint resist layer. The stamp can be selectively coated with metals such as Nickel specifically in the regions of protrusions of the stamp forming the respective recesses in the imprint resist layer. As a result, the NIL resist will not harden and/or undergo a cross-linking reaction in these regions where the coating has been applied. Thus, the remaining bottom residue can be easily stripped and thereby removed, providing access to the electrically conductive layer underneath the NIL resist.

Hence, only one time a “complex” master stamp/mold fabrication for example with Two-Photon Grayscale Lithography can be formed. Next, in mass production, a plurality of component layers can be formed with one master stamp. Hence, vias and fine line patterns with different heights can be stamped in one common stamping process step. With respect to conventional lithographic etching processes a plurality of working steps can be replaced by one printing step. Furthermore, an alignment accuracy of less than 1 μm can be provided such that landless via manufacturing is possible. Hence, a high accuracy with respect to LDI machines. Furthermore, by the NIL process 2.5D and 3D patterns for the predefined structures can be formed.

The imprint resist layer may be an UV (ultraviolet) curable (NIL) resist layer which is coated on the surface of the electrically conductive layer for example by dispensing or spin coating. The dielectric curable imprint resist layer may have a temperature stability up to 260 degrees Celsius and a coefficient of thermal expansion (CTE) below 80, preferably below 60. The thickness of the imprint resist layer may be 0.1 μm to 25 μm, preferably 1 μm to 10 μm. The imprint resist layer may have a low shrinkage of the during hardening, as the shrinkage directly effects the achievable resolution and the accuracy. The shrinkage of the imprint resist layer due to UV or thermal curing can be reduced via a specific mold designed for compensating the shrinkage of the resist during hardening, in which the layer structure is placed during curing. The steps of stamping and curing may occur simultaneously.

Next, in the through hole of the printable resist layer, a respective electrically insulating material or an electrically conductive material can be filled. The electrically conductive material, such as copper, can be filled in the respective through hole by plating and respective filling proceedings. During the filling process (e.g. the plating process) of the through hole, the other areas of the electrically conductive layer are coated with the imprint resist layer and will not be coated with the electrically conductive material. Consequently, the imprint resist layer can be simultaneously used as a mask and as protective film during plating.

By the approach of the present disclosure, the nanoimprint lithography (NIL) is used for a mass production of a component carrier (e.g. a PCB). The NIL process flow according to the disclosure enables a reduction process steps. According to the present disclosure, the imprint resist layer can be used as an etching protection and/or plating protection. Furthermore, in an exemplary embodiment, the removal of the imprint resist layer may no longer necessary. In such an embodiment further process step during etching to protect the areas which should not be removed may be obsolete. Hence, it is not necessary to add another resist if the imprint resist layer is already applied to a respective surface before etching.

Hence, no separate additional protection layers are necessary such that a more efficient process in particular for mass production is provided. Furthermore, a further necessary etching step can be combined with the removing step of the bottom residue, such that in one process step, a plurality of different sections, such as an overfilled layer and a respective bottom residue, can be removed in one step.

Additionally, the resolution of conventional LDI process is limited by the pixel size and penetration depth of the applied wavelength exposed by the laser which induces the cross-linking reaction of the resin, in particular the hardening of the resin. The resolution of the design applied thereby suffers, due to partially reflected laser light which consequently leads to a maximum achievable penetration depth. By applying the NIL process according to the approach of the present disclosure, as the resolution of the process is defined by the precisely manufactured molt and stamp, which enables the manufacturing of a patterned structure with a fine resolution. Thus, significantly smaller vias having a smaller diameter may be manufactured with respect to conventional LDI processes.

Summarizing, the disclosure relates to a component carrier, such as a PCB containing embedded multi-dies and fine interconnection structures as well as an economic manufacturing route for the same.

According to a further exemplary embodiment, the electrically conductive layer is applied onto a temporary carrier structure, and the temporary carrier structure is removed after stamping the predefined structures, such that the layer structure for the component carrier is formed.

The temporary carrier structure is configured for providing a sufficient stability during the manufacturing of the component layer structure and the component carrier, respectively. The temporary carrier is mounted temporarily to the electrically conductive layer and can be removed after the conductive layer has been manufactured. The electrically conductive layer may be fixed directly to the temporary carrier structure. Alternatively, the electrically conductive layer may be fixed indirectly to the temporary carrier structure, such that for example a plurality of intermediate layer structures may be interposed.

The temporary carrier structure may comprise a temporary carrier made of glass material in order to be transparent for UV light. The temporary carrier may be coated with a release layer, in particular a UV release layer, arranged between the electrically conductive layer and the temporary carrier. Hence, the temporary carrier can be removed and the application of UV light, for example.

Finally, for example after curing (by electromagnetic radiation, temperature and/or pressure), the temporary carrier structure can be removed such that the layer structure (for the component carrier is formed. Hence, a respective layer structure for a component carrier can be provided).

According to a further exemplary embodiment, the at least one recess comprises a bottom residue covering the electrically conductive layer. The bottom residue generated in the stamping step can be used as a protection in further etching and filling (e.g. plating) steps.

Subsequent to the step of stamping, the predefined structures comprise at least one recess comprising a bottom residue covering the electrically conductive layer. The recesses may form large and fine structures at the same time. Hence, it is also possible to form at the same time first layer interconnection structures from Chips to low density areas of the board in one step.

The recesses may form through holes but also blind holes, lines or trenches which are representative for conductive structures to be formed, for example. The line/space between adjacent recesses may be formed by stamping and subsequent (i.e. differential) etching smaller than 1 μm, in particular smaller than 0.2 μm or even less.

The bottom residue covering the electrically conductive layer may comprise for example at thickness of less than 300 nm, in particular less than 100 nm. The bottom residue of the imprint resist layer in the recess is removed by a subtractive removing process such that the respective recess provides access to the electrically conductive layer through the imprint resist layer. For example, the bottom residue may be removed by plasma supported etching or by etching, in particular dry etching. For cleaning the etched recess an optional cleaning step, e.g. wet or dry cleaning steps, can be conducted. For example, a further plasma desmear process may be applied. Hence, a cleaned through hole in the imprint resist layer and hence an access to the electrically conductive layer is provided.

According to a further exemplary embodiment, the bottom residue of the imprint resist layer in the recess is removed by a subtractive removing process such that the respective recess provides access to the electrically conductive layer through the imprint resist layer.

According to a further exemplary embodiment, the method further comprises after removing the bottom residue of the imprint resist layer in the recess the step of etching the electrically conductive layer in the regions accessible through the imprint resist layer such that respective filling structures are formed in the electrically conductive layer. The exemplary embodiment is related to a subtractive process. Thus, a selective etching of the electrically conductive layer is possible. The filling structures in the electrically conductive layer with an electrically insulating material. Hence, the electrically conductive structure is etched (e.g. by wet etching) and hence patterned by an etchant. The etched portions of the electrically conductive layer are filled by an electrically insulating material which forms the filling structures. Hence, between the nonconductive filling structures, electrically conductive structures, such as vias, trenches and lines, respectively are formed in the electrically conductive layer.

According to a further exemplary embodiment, the method further comprises after removing the bottom residue of the imprint resist layer in the recess the step of filling in the recess with an electrically conductive material such that respective filling structures, in particular a via, in the layer structure is formed. Hence, a layer structure may be formed, wherein a via extends from the electrically conductive layer through the insulating imprint resist layer.

According to a further exemplary embodiment a further conductive filling material is formed onto the electrically conductive material in the via and/or in respective recesses to generate a conductive surface section, in particular by plating.

According to a further exemplary embodiment, before forming the further conductive filling material the imprint resist layer and/or the via is coated by a seed layer for forming of the further conductive filling material. Hence, an over-plating of the vias can be obtained as well as the copper traces themselves. The exemplary embodiment is related to a mSAP process (modified Semi Additive Process).

In the context of the present application, the term “seed layer” may denote a thin metallic layer which may be formed by electroless plating. Electroless plating may denote a formation of the seed layer by a plating process which does not involve application of electricity to a structure to be plated with the seed layer. For example, electroless plating may involve formation of a chemical metal film as the seed layer. Additionally or alternatively, electroless plating may comprise forming the seed layer by sputtering.

In the context of the present application, the term “electroplating structure” may denote a metallic structure formed by electroplating. For electroplating, and in particular galvanic plating, of electrically conductive material on a seed layer formed by electroless plating, water-based solutions or electrolytes may be used which contain metal to be deposited as ions (for example as dissolved metal salts). An electric field between a first electrode (in particular an anode) and a preform of the component carrier to be manufactured as second electrode (in particular a cathode) may force (in particular positively charged) metal ions to move to the second electrode (in particular cathode) where they give up their charge and deposit themselves as metallic material on the surface of the through hole.

In the context of the present application, the term “electroplating protection structure” may denote a structure made of a material on which no (or at least no noteworthy amount of) metal can be deposited by electroplating. Thus, the electroplating protection structure may be an anti-plating dielectric structure and may particularly denote an electrically insulating structure made of a material on which plating of a metal is inhibited, disabled or made impossible. This can be accomplished by providing the anti-plating dielectric structure from a non-adhesive or very poorly adhesive dielectric material with preferably hydrophobic properties on which electroplated metal does not adhere. Also, non-polarized properties of the electroplating protection structure may be advantageous. For example, the electroplating protection structure may comprise at least one of a group consisting of a release ink, polytetrafluoroethylene, and polyimide. More generally, any hydrophobic material may be appropriate for forming the electroplating protection structure. It is also possible that such a non-adhesive or poorly adhesive structure may be made of a waxy material or a suitable varnish.

According to a further exemplary embodiment, the temporary carrier structure comprises a temporary carrier layer, in particular a glass carrier layer, and a release layer, in particular an electromagnetic radiation sensitive release layer, coupled to the electrically conductive layer. Hence, after the layer structure has been cured and solidified, upon treatment of the release layer by ultraviolet radiation, the binding effect of the release layer is reduced such that the release layer together with the temporary carrier layer can be removed.

According to a further exemplary embodiment, the electrically conductive layer comprises copper. The electrically conductive layer is in particular a copper foil comprising a thickness of 1 μm to 10 μm (micrometers).

According to a further exemplary embodiment, the imprint resist layer comprises a thickness of 0.1 μm to 50 μm, in particular 0.5 μm to 20 μm, more in particular 1 μm to 10 μm. The imprint resist layer comprises in particular electromagnetic radiation curable material, heat curable material and/or a UV curable material. For example, the imprint resist layer comprises in particular at least one of silicon dioxide SiO₂, titanium dioxide TiO₂, SiO₂—Al₂O₃ and glass compounds. Hence, nanofillers such as SiO₂ and zeolite may be used. Respective fillers may be plasma etchable. Furthermore, the imprint resist layer may comprise (amongst others) SU-8 based epoxy negative resists and an organic-inorganic hybrid polymer composite, Benzocyclobutene (BCB), such as Cyclotene.

According to a further exemplary embodiment, the imprint resist layer is added to the electrically conductive layer by coating, in particular by dispensing coating or spin coating. Spin coating is a procedure used to deposit uniform thin films onto flat substrates. Usually, a small amount of imprint resist material is applied on the center of the electrically conductive layer. The electrically conductive layer is then rotated with high speed to spread the coating material by centrifugal force. Furthermore, printing methods, such as ink-jet printing, may be applied in order to add the imprint resist layer.

According to a further exemplary embodiment, the predefined structures in the imprint resist layer are stamped by roll-to-plate process or a plate-to-plate process. By the roll-to-plate process, the stamp is a cylinder, which comprises at the surface the fine structures (in negative shape) (i.e. respective recesses and protrusions). The plate-shaped imprint resist layer is driven through the stamping machine such that the cylinder stamp rolls over the imprint resist layer under pressure, such that the respective recesses in the imprint resist layer are mechanically formed. By the plate-to-plate process, the stamp is a plate which comprises at the surface the fine structures. The plate-shaped stamp is pressed onto the surface of the imprint resist layer, such that the respective recesses in the imprint resist layer are mechanically formed.

According to a further exemplary embodiment, the filling structures in the electrically conductive layer are spaced apart from each other with a distance less than 25 μm, in particular less than 15 μm, more in particular less than 8 μm and more in particular less than 3 μm, in particular less than 2 μm. For example, a plate-to-plate NIL imprinting may be possible with an alignment accuracy of at least 2 μm. Hence, filling structures forming electrically connecting wiring may be accomplished by landless vias (which may be advantageous in particular for high-frequency applications). Moreover, an aspect ratio width/height of the filling structures is below a ratio of 1, in particular ratio of below 0.5, more in particular ratio of below 0.2.

According to a further exemplary embodiment, the subtractive removing process for removing the bottom residue in the recess is a wet etching process or a dry etching process, in particular a reactive ion etching process, or a plasma supported process, such as a reactive ion etching or plasma supported etching process. Plasma Desmear uses controlled chemical reactions to clean residues from the inside of the recess of the imprint resist layer or a respective hole in the electrically conductive layer. By using a Plasma Desmear an unwanted removal of material of the imprint resist layer surrounding the recess and respective material of the electrically conductive layer can be minimized as the used plasma (reactive gas) can be selected to selectively remove different materials.

According to a further exemplary embodiment, the filling structures are coated with an adhesion promoter layer for improving the binding to the electrically insulating material or the electrically conductive material in the subsequent filling (e.g. plating) step. The adhesion promoter layer may comprise at least one of Silanes and Siloxanes, quaternary ammonium polymer and their compositions. The barrier layer comprises at least one of Siloxanes, Silicon Nitride and their compositions and metals as Tin, Zinc, Nickel or Aluminum, Copper and their mixtures or alloys.

According to a further exemplary embodiment, the imprint resist layer is removed subsequent to the etching of the electrically conductive layer such that a surface of the electrically conductive layer is uncovered. The imprint resist layer may be removed by a dry etching process or a wet etching process. Hence, the imprint resist layer is used as a temporary sacrificial layer and is removed before the layer structure is further processed and further functional areas are added.

Furthermore, in particular a further electrically insulating layer, in particular a layer consisting of resin or polymer or a further imprint resist layer, is formed onto the uncovered electrically conductive structure.

According to a further exemplary embodiment, a further electrically conductive layer is formed onto the further electrically insulating layer. Hence, further buildup structures can be formed such that a complex multilayer layer structure for the component carrier can be formed. The embodiment of the disclosure can be combined with conventional subtractive and/or mSAP processes. Thus, it is possible to manufacture for instance a high-density layer with the inventive NIL process, whereas the other layers added to achieve the final build-up can be manufactured with conventional process. This enables the production of economical products.

According to a further exemplary embodiment, in the electrically conductive layer at least one via hole is formed before the imprint resist layer is added to the electrically conductive layer. To protect the via hole, the stamp can be coated by Nickle (Ni) or Chrome (Cr) to avoid curing of the resist in the hole. Uncured resist can be removed later on e.g. by washing. The imprint resist layer is stamped in such a way that the imprint resist layer comprises a resist layer through hole, wherein the imprint resist layer is aligned with the electrically conductive layer such that the via hole of the electrically conductive layer matches with the resist layer through hole. If residue falls into the previously formed via hole in the electrically conductive layer during the stamping step, for example a plasma supported etching process can be applied in order to clean up the via hole. Hence, by the exemplary embodiment, the respective recesses, trenches will blind holes or through holes in the electrically conductive structure are formed for example by etching processes in a previous manufacturing step before applying the imprint resist layer.

According to a further exemplary embodiment, the electrically conductive material is filled (e.g. by plating) for forming a via in the via hole of the electrically conductive layer and the resist layer through hole such that an excess portion of the electrically conductive material (e.g. excess plated copper) is provided.

Specifically, only some recesses of the imprint resist layer are filled with electrically conductive material, while other recesses, in particular providing the bottom layer, are kept free of the electrically conductive material.

According to a further exemplary embodiment, in or after the step of removing the bottom residue of the imprint resist layer, the excess portion in the resist layer through hole of the imprint resist layer is removed, in particular by etching. Hence, simultaneously the step of removing and etching can be conducted. Specifically, the excess portion of the electrically conductive material is removed and additionally the bottom layer of the imprint resist layer in the unfilled recesses as well as the below located sections of the electrically conductive layer are removed. Specifically, the electrically conductive layer may be etched by wet etching and the imprint resist layer by dry etching.

According to a further exemplary embodiment, a further electrically insulating layer, in particular a pre-preg or a further imprint resist layer, is formed onto the imprint insulating layer. The recess of the imprint resist layer is filled with a material identical to the further electrically insulating layer or by a material different to the further electrically insulating layer. Thus, the dielectric material, filling the recesses between the traces comprises a Nil imprint resist layer and conventional resins used in the PCB industry.

Hence, by the present exemplary embodiment, the imprint resist layer is used as a permanent imprint resist (NIL) layer which is part of the final component carrier. For example, a further imprint resist layer may be applied and a respective further nanoimprint step for structuring the further imprint resist layer can be applied.

According to a further exemplary embodiment, the imprint resist layer is removed and a further electrically insulating layer, in particular a pre-preg or a further imprint resist layer, onto the electrically conductive layer, wherein the filling structures in the electrically conductive layer are filled with electrically insulating material identical to the further electrically insulating layer or by a material different to the further electrically insulating layer.

The layer structure manufactured by the inventive method can be combined with conventional subtractive and/or mSAP processes. Thus, it is possible to manufacture for instance a high-density layer with inventive NIL process, whereas the other layers added to achieve the final build-up can be manufactured with conventional process. This enables the production of economical products.

In the following, exemplary embodiments of the component carrier will be summarized:

According to an exemplary embodiment the at least one recess forming part of the filling structure comprises tapering sidewalls.

According to a further exemplary embodiment, a roughness Ra of a surface, in particular a sidewall surface, of the imprint resist layer delimiting the surface profile is not more than 100 nm, in particular not more than 50 nm.

According to a further exemplary embodiment, the at least one recess forms a through hole so that at least one surface portion of the electrically conductive layer exposed at the recess.

According to a further exemplary embodiment, at least one further conductive filling material is formed onto the electrically conductive material filled in the respective recess forming the filling structure.

According to a further exemplary embodiment, the component carrier further comprises an electrically conductive seed layer selectively lining the filling structure of the imprint resist layer and in particular the electrically conductive material filled in the respective recess forming the filling structure.

According to a further exemplary embodiment, at least one of the electrically conductive material and the further conductive filling material are plated layers, wherein the electrically conductive material and the further conductive filling material are connected in a landless way.

According to a further exemplary embodiment, the component carrier further comprises a further layer structure onto which the layer structure is formed, wherein the further layer structure comprises in particular at least one laminated printed circuit board layer stack.

According to a further exemplary embodiment, the component carrier further comprises a component mounted on the imprint resist layer by a connection structure, in particular by one of a solder structure, a sintered structure and a thermal compression bonding structure, arranged between the component and the imprint resist layer.

According to a further exemplary embodiment, the component carrier further comprises two components arranged side-by-side at least partially on the imprint resist layer and being electrically coupled with each other by electrically conductive connection structures at and/or lateral from the imprint resist layer, in particular at and/or lateral from a protrusion of the imprint resist layer.

According to a further exemplary embodiment, at least one of the two components comprises pads having different pitch sizes being electrically coupled with the electrically conductive connection structures having different pitch sizes by connection structures, in particular solder structures, having different dimensions.

According to a further exemplary embodiment, at least one first pad of the pads has a smaller pitch size than at least one second pad of the pads having a larger pitch size, wherein the at least one first pad is electrically coupled with at least one first of the electrically conductive connection structures on the imprint resist layer, and wherein the at least one second pad is electrically coupled with at least one second of the electrically conductive connection structures on a laminated printed circuit board layer stack apart from the imprint resist layer.

According to a further exemplary embodiment, wherein at least a portion of the via protrudes beyond the imprint resist layer and thereby forms at least one via protrusion for electric connection with an electronic periphery, in particular for electric connection with a surface mounted component.

The component carrier may comprise a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact. The term “layer structure” may particularly denote a continuous layer, a patterned layer or a plurality of non-consecutive islands within a common plane.

In an embodiment, the component carrier is shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connection. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylether PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high-frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten and magnesium. Although copper is usually preferred, other materials or coated versions thereof are possible as well, in particular coated with supra-conductive material or conductive polymers, such as graphene or poly (3,4-ethylenedioxythiophene) (PEDOT), respectively.

The at least one component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay could be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

According to a further exemplary embodiment, after removing the temporary carrier structure, the electrically conductive layer comprises noncovered electrically conductive pads to which a component is contactable.

According to a further exemplary aspect of the present disclosure an imprint resist material is provided configured for being used for an imprint resist layer for a layer structure of a component carrier.

Specifically, the imprint resist material is configured for being used for prepolymer composition, characterized in that it is used for continuous structuring and in-situ UV curing in a NIL imprint process, preferably in a roll-to-plate process, which stays in a final build-up.

Specifically, the imprint resist material is configured for being used as an etching production during an etching process for structuring a surface.

Specifically, the imprint resist material is configured for being used as one at least further dielectric material in a component carrier.

According to a further exemplary embodiment the imprint resist layer comprises an electrically insulating material.

According to a further exemplary embodiment the imprint resist layer has an adhesion of more than 600 Nm. Adhesion is the tendency of dissimilar particles or surfaces to cling to one another. The forces that cause adhesion may be intermolecular forces responsible for the function of various kinds of stickers and sticky tape fall into the categories of chemical adhesion, dispersive adhesion, and diffusive adhesion.

According to a further exemplary embodiment the imprint resist layer comprises temperature resistance between 200° C. and 300° C., in particular 230° C. to 260° C. The imprint resist layer may be in particular a cured cross-linked resist material having the temperature resistance between 230° C. to 260° C. The higher the cross-linking, the higher the modulus-depending on used base oligomers.

According to a further exemplary embodiment the imprint resist layer comprises material of a flame retardancy class 4 (FR4). FR4 may be a composite material composed of woven fiberglass cloth with an epoxy resin binder that is flame resistant (self-extinguishing). FR-4 glass epoxy is a high-pressure thermoset plastic laminate grade with good strength to weight ratios. With near zero water absorption, FR-4 is used as an electrical insulator possessing considerable mechanical strength.

According to a further exemplary embodiment the imprint resist layer comprises material having a glass-transition temperature between 120° C. and 200° C., in particular between 135° C. and 170° C.

According to a further exemplary embodiment the imprint resist layer has a (Young) modulus below a glass-transition temperature (in the fully cured stage) of 1000 MPa to 14000 MPa, in particular 5000 MPa to 13000 MPa.

According to a further exemplary embodiment the imprint resist layer has a (Young) modulus above a glass-transition temperature (i.e. in a reflow state) of 60 MPa to 800, in particular 100 MPa to 600 MPa. The glass-liquid is the gradual and reversible transition in amorphous materials (or in amorphous regions within semicrystalline materials) from a hard and relatively brittle “glassy” state into a viscous or rubbery state as the temperature is increased. An amorphous solid that exhibits a glass transition is called a glass. The reverse transition, achieved by supercooling a viscous liquid into the glass state, is called vitrification. The glass-transition temperature Tg of a material characterizes the range of temperatures over which this glass transition occurs. It is lower than the melting temperature.

These properties may ensure that the material of the imprint resist layer is sufficiently mechanically strong for enabling a precise design of electrically conductive traces, vertical through connections, etc. in the imprint resist layer. At the same time, these properties may ensure that the material of the imprint resist layer has a sufficient elasticity to buffer thermal and/or mechanical stress.

According to a further exemplary embodiment the imprint resist layer has a thermal expansion coefficient below a glass-transition temperature of 10 ppm/K to 40 ppm/K, in particular 20 ppm/K to 40 ppm/K. These values may suppress thermal stress in an interior of the component carrier.

According to a further exemplary embodiment the imprint resist layer has a thermal expansion coefficient above a glass-transition temperature of 50 ppm/K to 100 ppm/K, in particular 60 ppm/K to 85 ppm/K. These values may suppress thermal stress in an interior of the component carrier. The higher the value of the thermal expansion coefficient (CTE) above Tg, the higher the reliability issue. The imprint resist layer may comprise non-woven glass fibers such that thermal expansion occurs in all directions. The thermal expansion coefficient is also driven by the amount of fillers. The thermal expansion coefficient decreases if the amount of filler increases. The imprint resist layer may have a filler content of 80% filler.

According to a further exemplary embodiment the imprint resist layer is formed with a fracture strain below a glass-transition temperature of is 2%. This may lead to advantageous mechanical properties of the imprint resist layer and a correspondingly manufactured component carrier.

According to a further exemplary embodiment the imprint resist layer is formed with a chemical shrinkage below 3%. Consequently, shrinkage-based curing stress in an interior of the component carrier may be avoided.

According to a further exemplary embodiment the imprint resist layer is formed with a moisture absorption below 0.1%, and/or a desmear rate below 0.006 g/min of 3%.

A Dk value of the material of the imprint resist layer (in particular of resin thereof) may be not more than 3, specifically for high-frequency applications. A Df value of the material of the imprint resist layer (in particular of resin thereof) may be not more than 0.003, specifically for high-frequency applications. As a result, an obtained component carrier may have excellent properties in terms of high-frequency behavior. If the filler content increases, the values for Dk and Df increase as well.

A number of press cycles which the material of the imprint resist layer may withstand may be in a range from 1 to 10. A number of reflow tests which the material of the imprint resist layer may withstand may be at least 6. This may allow to manufacture a component carrier using an imprint resist layer with a stack thickness being selectable over a sufficiently broad range. The material of the imprint resist layer may be characterized by a peel test on copper of at least 600 N/m. A press cycle of the imprint resist layer may withstand from 6 up to 10 times.

A desmear rate of the material of the imprint resist layer may be at least 0.006 g/min. The material of the imprint resist layer may be characterized by a UL listing (in accordance with the industrial standard IEC/DIN EN 60695-11-10 and -20 in the latest version being in force at the priority date of the present application) of V1 to V0 (which may ensure safety against flammability). The mentioned material properties may simplify processing of the imprint resist layer. The imprint resist layer comprises aromatic hydrocarbons, such as PPE (poly (p-phenylene ether) PPE, BCB (Benzocyclobutene), Epoxy and/or halogenated polyimide. Specifically, the imprint resist layer is configured for being used in a SLID soldering process, wherein temperatures of 25° C. for 0.5 to 1 hour are applied.

According to a further exemplary embodiment the imprint resist layer comprises a fully cured polymer based on at least one of the following group comprising epoxies, acrylates, polyphenylenether, polyimide, polyamide and polyetheretherketon, poly (p-phenylene ether) (PPE), Bisbenzocyclobutene (BCB), and/or Polybenzoxabenzole (PBO).

Specifically, a combination of the oligomers listed above may be used for a (specifically permanent) imprint resist layer (i.e. an UV-NIL resist). For example, a combination of BCB, PPE and SU8 loaded can be used with a high amount of more than 80% of encapsulated inorganic, round shape SiO₂ nanofillers and a halogen-free material.

For example, BCB (Divinylsiloxane-bis-benzocyclobutene (DVS-bis-BCB, or BCB), e.g. CYCLOTENE™ DuPont Series advanced electronic resins) are photopolymers. These polymers are derived from B-staged bisbenzocyclobutene (BCB) chemistry.

For example, PPE (e.g. Sabic NORYL SA9000 resin) is a modified, low molecular weight, bi-functional oligomer based on polyphenylene ether (PPE) with vinyl end-groups (used in Megtron 6 &7 Materials).

For example, SU-8 (e.g. Kayaku Advanced Materials SU-8) is a high contrast, epoxy-based photoresist designed for micromachining and other microelectronic applications.

A chloride content of the resin may be below 30 ppm. Specifically, the imprint resist layer may be almost free of halogens (e.g. less than 30 ppm) which are ionic and not bonded with a polymer. The halogens may be washed out with multiple water wash steps.

Advantageously, no salt formation should occur during the processing of the resin. Moreover, a high cross-linking capability of the resin may be advantageous. A low porosity may be preferred to avoid undesired phenomena such as cracks, migration, etc.

According to a further exemplary embodiment the imprint resist layer comprises polymer- or oligomer-based building blocks, wherein at least one of the building blocks is based on one of the above-mentioned polymers.

According to a further exemplary embodiment the imprint resist layer at at least one of the building-blocks has at least one functional group covalently bond to another one of the least one building block. The covalently bound functional group is responsible for the cross-linking connection.

According to a further exemplary embodiment the at least one functional group is selected from one of the group comprising a thiol group selected from the group of 3-mercaptopropionates, 3-mercaptoacetates, thioglycolates and alkylthiols, and/or a double bond selected from the group of acrylates, methyl acrylates, vinyl ethers, allyl ethers, propenyl ethers, alkenes, dienes, unsaturated esters and allyl triazines, allyl isocyanates and N-vinyl amides.

According to a further exemplary embodiment the imprint resist layer comprises a prepolymer having at least one photoinitiator, contained in an amount of 0.1 wt. % to 10 wt. %, in particular 0.5 wt. % to 5 wt. %.

According to a further exemplary embodiment the imprint resist layer is in particular a fully cured resin, wherein the imprint resist layer further comprises filler particles such as in an amount of 1 wt. % to 10 wt. %, in particular 1 wt. % to 3 wt. %.

According to a further exemplary embodiment the filler particles comprise inorganic fillers, wherein the inorganic fillers are in a crystalline state and in particular encapsulated. The inorganic fillers may be nanofillers which can be coated to avoid agglomeration and reduce thixotropy. Porous fillers may have lower Dk because of air but they can absorb chemistry. Therefore, porous fillers have a hydrophobic silane coating as it is the case in Rogers 3000 materials, at the same time mixing of fillers in the resin matrix is easier. Halogenated organics, hydrophobic polymers and covalent bonded halogen can be used for the fillers so that a high flame retardant can be achieved. The imprint resist layer may comprise high inorganic filler with an aromatic content. The inorganic fillers may have a round smooth shape, which is better than needles shape.

According to a further exemplary embodiment the filler particles comprise a size (e.g. an average size to be calculated according to an arithmetic average) of less than 0.1 μm.

According to a further exemplary embodiment the filler particles comprise Talcum (i.e. a layered silicate), zeolite and/or fused SiO₂. SiO₂ or Zeolite nanofiller usually agglomerate but with coating this agglomeration can be reduced and also tixotrophy may be reduced.

According to a further exemplary embodiment the filler particles are of plasma etchable material.

According to a further exemplary embodiment, the imprint resist layer comprises less than 95% (weight percentage) filler particles, in particular 80% to 95% filler particles, in relation to an entire weight of the material of the imprint resist layer. More filler particles cause less shrinking of ink during UV-curing, for example, and result in a better CTE at the same time. Furthermore, a better flame-retardant property is achieved at the same time.

According to a further exemplary embodiment the imprint resist layer comprises a viscosity of 0.01 Pas to 1 Pas.

The aspects defined above and further aspects of the present disclosure are apparent from the examples of embodiment to be described hereinafter and are explained with reference to the examples of embodiment. The disclosure will be described in more detail hereinafter with reference to examples of embodiment but to which the disclosure is not limited.

### BRIEF DESCRIPTION OF THE DRAWINGS

FIG. 1A, FIG. 1B, FIG. 1C, FIG. 1D, FIG. 1E, FIG. 1F, FIG. 1G, and FIG. 1H illustrate a schematic view of a method of manufacturing a layer structure for a component carrier with a temporary imprint resist layer, a filling of electrically insulating material in the electrically conductive layer, and removing the imprint resist layer according to an exemplary embodiment.

FIG. 2A, FIG. 2B, FIG. 2C, FIG. 2D, FIG. 2E, FIG. 2F, FIG. 2G, FIG. 2H, FIG. 2I, and FIG. 2J illustrate a schematic view of a method of manufacturing a layer structure for a component carrier with a permanent imprint resist layer, a forming of a via in an electrically conductive structure, and leaving the imprint resist layer in the layer structure according to an exemplary embodiment.

FIG. 3A, FIG. 3B, FIG. 3C, FIG. 3D, FIG. 3E, FIG. 3F, FIG. 3G, FIG. 3H, FIG. 3I, and FIG. 3J illustrate a schematic view of a method of manufacturing a component carrier with a plurality of layer structures with a permanent imprint resist layer, a forming of a via in an electrically conductive structure, and leaving the imprint resist layer in the layer structure according to an exemplary embodiment.

FIG. 4A, FIG. 4B, FIG. 4C, FIG. 4D, FIG. 4E, FIG. 4F, FIG. 4G, FIG. 4H, FIG. 4I, and FIG. 4J illustrate a schematic view of a method of manufacturing a component carrier with a plurality of layer structures with a temporary imprint resist layer, forming of a via in an electrically conductive structure, and removing the imprint resist layer according to an exemplary embodiment.

FIG. 5 illustrates cross-sectional views of structures obtained during carrying out a method of manufacturing a component carrier according to another exemplary embodiment of the disclosure.

FIG. 6, FIG. 7, and FIG. 8 illustrate cross-sectional views of layer structures to which a component is coupled according to another exemplary embodiment of the disclosure.

FIG. 9 and FIG. 10 illustrate a component carrier according to still another exemplary embodiment of the disclosure.

FIG. 11 shows a device for stamping a surface profile in an imprint resist layer using a working mold according to an exemplary embodiment.

FIG. 12 illustrates a component carrier according to still another exemplary embodiment of the disclosure.

FIG. 13 and FIG. 14 illustrate a component carrier according to yet another exemplary embodiment of the disclosure.

FIG. 15, FIG. 16, and FIG. 17 show three-dimensional views of stamped design layers used for manufacturing component carriers according to exemplary embodiments of the disclosure.

### DETAILED DESCRIPTION OF EXEMPLARY EMBODIMENTS

The illustrations in the drawings are schematically presented. It is noted that in different figures, similar or identical elements or features are provided with the same reference signs or with reference signs, which are different from the corresponding reference signs only within the first digit. In order to avoid unnecessary repetitions elements or features which have already been elucidated with respect to a previously described embodiment are not elucidated again at a later position of the description.

Further, spatially relative terms, such as “front” and “back”, “above” and “below”, “left” and “right”, et cetera are used to describe an element's relationship to another element(s) as illustrated in the figures. Thus, the spatially relative terms may apply to orientations in use which differ from the orientation depicted in the figures. Obviously, all such spatially relative terms refer to the orientation shown in the figures only for ease of description and are not necessarily limiting as an apparatus according to an embodiment of the disclosure can assume orientations different than those illustrated in the figures when in use.

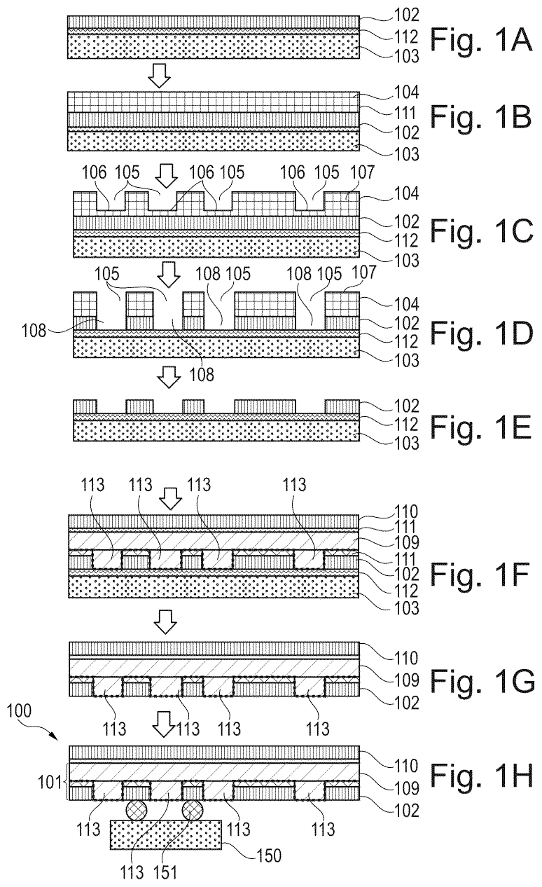

FIG. 1A to FIG. 1H includes a schematic view of a method of manufacturing a layer structure 101 for a component carrier 100 with a temporary imprint resist layer 104 and a filling of electrically insulating material 113 in the carrier layer which is in particular an electrically conductive layer 102 according to an exemplary embodiment. Specifically, FIGS. 1A to 1H describe a copper structuring process with a sacrificial NIL resist layer 104.

In FIG. 1A, the electrically conductive layer 102 applied onto the temporary carrier structure 103, e.g. a glass carrier or metal (e.g. copper) foil, is provided. The temporary carrier structure 103 is coated with a release layer 112 sensitive to electromagnetic radiation and/or heat and the electrically conductive layer 102, e.g. a copper foil, of 1 μm to 10 μm thickness. By the shown method, the initial copper layer thickness can be the same as the final structured thickness of the copper layer. Hence, no further etching or layer buildup of the electrically conductive layer 102 is necessary.

In FIG. 1B, the imprint resist layer 104, e.g. a sacrificial curable NIL resist sensitive to electromagnetic radiation and/or heat, is added onto the electrically conductive layer 102. In particular, the imprint resist layer 104 is coated on the surface of the electrically conductive layer 102 with dispensing or spin coating or ink jet printing. Before, the electrically conductive layer 102, e.g. the copper foil, is coated with an adhesion promoter layer 111 or a barrier layer to minimize migration. The adhesion promoter layer 111 comprises Silanes or Siloxanes and their compositions as well as metals as Tin, Zinc, Nickel, Aluminum, Copper, and their mixtures. The dielectric curable resist layer 104 may have a temperature stability up to 260 degrees. The thickness of the NIL resist layer 104 may be 0.1 μm to 25 μm.

In FIG. 1C, predefined structures are stamped, e.g. by a NIL process, into the imprint resist layer 104 by a predefined stamp, wherein the predefined structures comprise at least one recess 105 comprising a bottom residue 106 covering the electrically conductive layer 102. Preferred NIL process for the first layer imprint resist layer 104 on glass carrier structure 102 may be a NIL roll-to-plate process. After or simultaneously to the structuring process via NIL stamping, curing is conducted and structures, e.g. recesses 105 and protrusions 107, are stamped into the resist. The NIL structuring processes comprises e.g. roll-to-plate as well as step and repeat plate-to-plate NIL processes.

In FIG. 1D, the bottom residue 106 of the imprint resist layer 104 in the recess 105 is removed by a subtractive removing process (e.g. by etching or by a plasma supported etching process) such that the respective recess 105 provides access to the electrically conductive layer 102 through the imprint resist layer. Specifically. before a trace formation (either etching or plating, obtained by e.g. chemical wet etching a further etching process (i.e. an anisotropic Copper micro etching process) for the microstructures, i.e. the respective recesses 105 and protrusions 107, is performed, a plasma supported etching step may be done to remove NIL resist bottom residues 106 on the bottom of the stamped pattern 105, 106 to open the copper structure of the copper foil 102 below by etching. As an alternative, the NIL working mold/stamp can be selectively coated with metals such as Nickel or Chromium in the regions of the recesses 105 and protrusions 107. Alternatively, a coating can be applied to the stamp, allowing to locally apply the NIL imprint resist layer 104 as those regions where the coating is applied, the imprint resist layer 104 will not harden and can be easily removed.

Furthermore, the electrically conductive layer 102 is etched in the regions accessible through the imprint resist layer 104 such that respective filling structures 108 are formed in the electrically conductive layer 102. The filling structures 108 comprises at least one of a through hole, blind holes and trenches. Hence, after e.g. plasma supported etching and opening the recesses 105 an e.g. copper microetch process is performed.

In FIG. 1E, the imprint resist layer 104 is removed subsequent to the etching of the electrically conductive layer 102 such that a surface of the electrically conductive layer 102 is uncovered. The imprint resist layer 104 is removed e.g. by a dry etching process.

In FIG. 1F, in particular a further electrically insulating layer 109, e.g. a pre-preg or a further imprint resist layer, is formed onto the uncovered electrically conductive structure 102. Thereby, the filling structures 108 in the electrically conductive layer 102 are filled with an electrically insulating material 113 being for example a different or the same material as a following further electrically insulating layer 109. Hence, the stack up is continued with the further electrically insulating layer 109 of a suitable prepreg, followed by e.g. an adhesion promoter 111, and a further electrically conductive layer 110, e.g. a copper foil. Alternatively, the stack up can be made without prepreg by coating a second layer of NIL photoresist as a further electrically insulating layer 109 and structuring the same.

In FIG. 1G, the temporary carrier structure 103 is removed, such that the layer structure 101 for the component carrier 100 is formed. Hence, after the stack-up has been completed, the glass carrier 103 is released by support of electromagnetic radiation, temperature and/or pressure in order to release the release layer 112. Further, a bottom layer of the electrically conductive layer 102, e.g. the copper foil, on the bottom of a flat surface with (copper) microstructures and sub microstructures may obtained with an accuracy from the NIL stamping, suitable for mounting components 150, e.g. by soldering. For example, compression bonding or with solder balls or copper balls 151 with tin cap may be applied. Furthermore, the electrically conductive layer 102, e.g. the copper foil, on the surface can be structured as well.

Accordingly, in FIG. 1H, a respective component 150, e.g. a microchip, is coupled e.g. via solder bumps 151 to the microstructures of the electrically conductive layer 102.

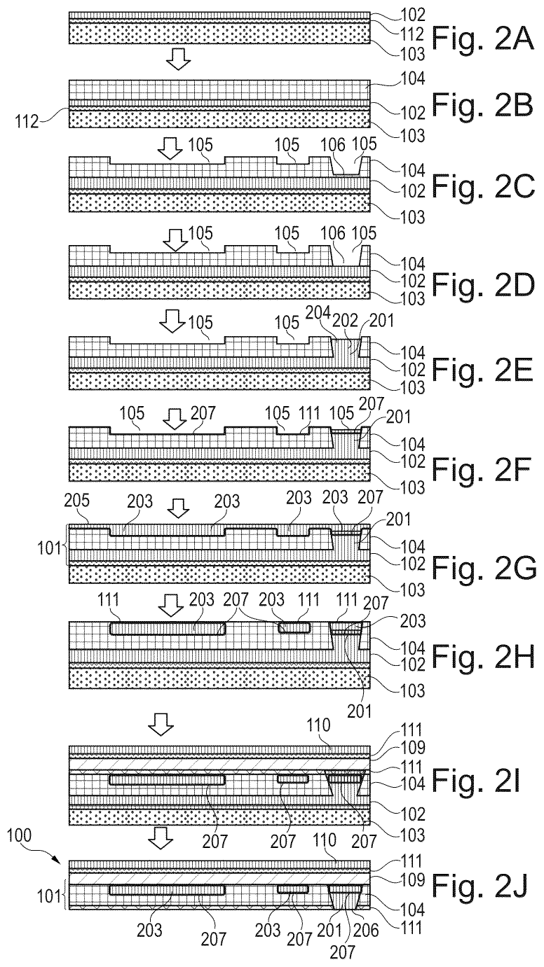

FIGS. 2A to 2J illustrate a schematic view of a method of manufacturing a layer structure 101 for a component carrier 100 with a permanent imprint resist layer 104 and a forming of a via 201 in a carrier layer which is in particular an electrically conductive structure 102 according to an exemplary embodiment. Specifically, a (e.g. copper) structuring process for a first, outer layer with a permanent printable NIL resist layer 104 is described.

In FIG. 2A, the electrically conductive layer 102 applied onto the temporary carrier structure 103, e.g. a glass carrier or a metal foil, is provided. The temporary carrier structure 103 is coated with a release layer 112 sensitive to electromagnetic radiation and/or heat and the electrically conductive layer 102, e.g. a copper foil, of 0.1 μm to 2 μm thickness.

In FIG. 2B, the imprint resist layer 104, e.g. a sacrificial curable NIL resist, is added onto the electrically conductive layer 102. In particular, the imprint resist layer 104 is coated on the surface of the electrically conductive layer 102 with dispensing or spin coating. Before, the electrically conductive layer 102, e.g. the copper foil, may be coated with an adhesion promoter layer 111. The permanent dielectric curable resist layer 104 may have a temperature stability up to 260° C. The thickness of the NIL resist layer 104 may be 0.1 μm to 25 μm.

In FIG. 2C, predefined structures are stamped, e.g. by a NIL process, into the imprint resist layer 104 by a predefined stamp, wherein the predefined structures comprise at least one recess 105 comprising a bottom residue 106 covering the electrically conductive layer 102. Preferred NIL process for the first layer imprint resist layer 104 on glass carrier structure 102 may be a NIL roll-to-plate process. After or simultaneously to the structuring process via NIL stamping, curing (e.g. by electromagnetic radiation, temperature and/or pressure) is conducted and filling structures, e.g. recesses 105 and protrusions 107, are stamped into the resist. The NIL structuring processes comprises e.g. roll-to-plate as well as step and repeat plate-to-plate NIL processes.

In FIG. 2D, the bottom residue 106 of the imprint resist layer 104 in the recess 105 is removed by a subtractive removing process (e.g. by etching or by a plasma supported process) such that the respective recess 105 provides access to the electrically conductive layer 102 through the imprint resist layer 104. In particular, those recesses 105 are treated with subtractive removing process at locations, where vias 201 are formed later on through the permanent imprint resist layer 104. Hence, the imprint resist layer 104 comprises after the subtractive removing process recesses 105 formed as blind holes or trenches which form no connection to the electrically conductive layer 102 and recesses 105 that provides through holes in the imprint resist layer 104 for obtaining later on a respective via 201.

Specifically, before a further etching process (i.e. a Copper micro etching process) for the microstructures, i.e. the respective recesses 105 and protrusions 107, is performed, a plasma supported step may be done to remove NIL resist bottom residues 106 on the bottom of the stamped pattern 105, 106 to open the copper areas of the copper foil 102 below. As an alternative, the NIL working mold/stamp can be selectively coated with metals such as Nickel or Chromium in the regions of the recesses 105 and protrusions 107.

In FIG. 2E, the recess 105 which provides access to the electrically conductive layer 102 is filled with an electrically conductive material 202 such that a via 201 through the imprint resist layer 104 is formed. Thus, the imprint resist layer 104 forms a protective coating of the surface, except for those regions where the NIL bottom residue 106 has been removed. Consequently, only the vias 201 will be filled. Specifically, after the plasma supported and opening the copper area in microvia recess 105, a copper via filling process is performed in order to plate and fill the copper microvia 201. During the copper via filling process of the microvia 201 the other areas and structures of the electrically conductive layer 102 are coated with the NIL printable resist layer 104 and will not be coated with electrically conductive material 202, e.g. copper, during the plating process. Before filling the via 201, a seed layer may be applied on the side walls of the imprint resist layer 104 to obtain reliable and conductive via 201.

In FIG. 2F, after the microvia filling step (e.g. after a bottom-up copper plating), the permanent NIL imprint resist layer 104 is coated optionally by Palladium, Titanium and/or Copper. Titanium and Copper can be added by a sputtering process. Further optionally, quaternary ammonium polymer or Silane can be added and function as an adhesion promoter. Further optionally, a barrier layer may be formed before a seed layer 207 is formed on the imprint resist layer 104. The seed layer 207 is optionally deposited onto the surface of the imprint resist layer 104 or the coating, respectively to be able to plate into the recesses 105. The seed layer 207 may be an electroless copper or conductive polymers as PEDOT (Poly-3,4-ethylendioxythiophen) or polythiophene process.

In FIG. 2G, a conductive surface made of excess electrically conductive material 205 and the further conductive filling material/layer 203 is formed by plating.

In FIG. 2H, after plating of the structures with plating processes the excess conductive filling material 205 (e.g. copper) on the surface of the imprint resist layer 104 is etched away and an embedded, micrometer size (e.g.) copper pattern with the further conductive filling material/layer 203 is formed. Hence, by etching of the very thin excess electrically conductive material 205 the structured traces/vias 203, 201 are formed.

In FIG. 2I, the embedded (copper) structures, e.g. the conductive filling material 203, and the surface of the imprint resist layer 104 are coated with an adhesion promotion layer 111. The adhesion promoter layer thickness may be below 300 nm and comprises Silanes or Siloxanes and their compositions as well as metals as Tin, Zinc, Nickel, Aluminum, Copper and their mixtures. The stack up is continued with the further electrically insulating layer 109 of a suitable prepreg, followed by e.g. an optional adhesion promoter layer 111, and a further electrically conductive layer 110, e.g. a copper foil. Alternatively, the stack up can be made without prepreg by coating a second layer of NIL photoresist as a further electrically insulating layer 109 and structuring the same.

In FIG. 2J, the temporary carrier structure 103 is removed, such that the layer structure 101 for the component carrier 100 is formed. Hence, after the stack-up has been completed, the temporary carrier 103 is removed. Further, a bottom layer of the electrically conductive layer 102, e.g. the copper foil, on the bottom a flat surface with (copper) microstructures and sub microstructures is removed by an etching process. On the bottom, finally a flat surface with copper via protrusion/pillar 206 forming pads 206 is obtained with an alignment accuracy below 0.2 μm suitable for mounting microchips and other components.

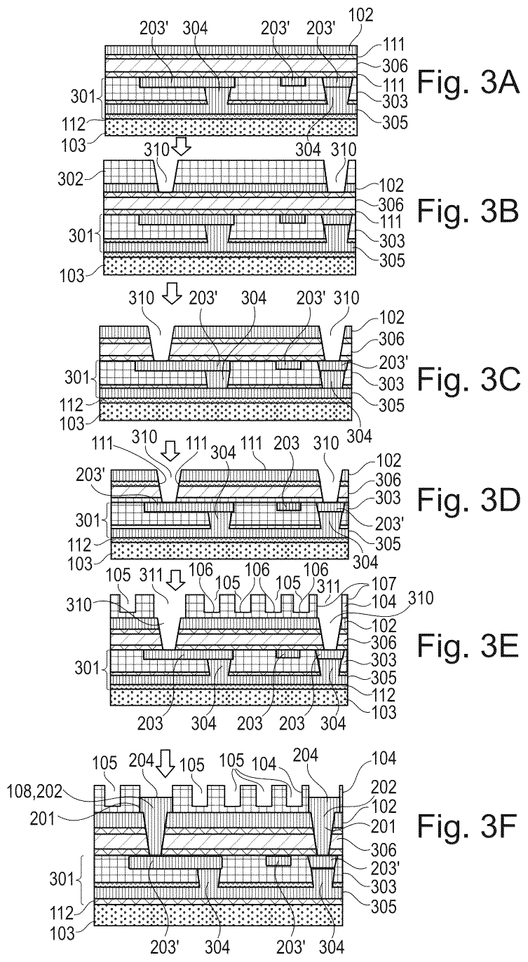

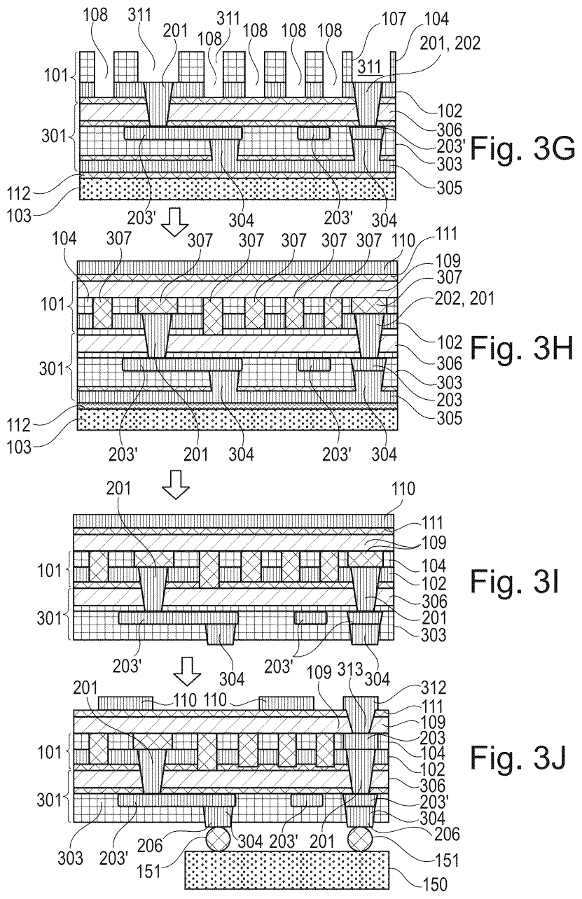

FIGS. 3A to 3J illustrate a schematic view of a method of manufacturing a component carrier 100 with a plurality of layer structures 101, 301 with a permanent (NIL) imprint resist layer 104 and a forming of a via 201 in a carrier layer which is in particular an electrically conductive structure 102 according to an exemplary embodiment. In the manufacturing method of FIGS. 3A to 3J a stack up formation with a NIL imprint resist layer 104 and subtractive process with focus on a Z-interconnection is illustrated.

In FIG. 3A, to build up the stack-up onto a further layer structure 301, a further permanent electrically insulating layer 303, e.g. a prepreg or a further (NIL) imprint resist layer, and a further electrically conductive layer 305, such as a copper foil of 1 μm to 10 μm thickness, are pressed on conductive (copper) structures, such as a further (copper) via 304. The further electrically conductive layer 305 is applied onto the temporary carrier structure 103, e.g. a glass carrier. The temporary carrier structure 103 is coated with a release layer 112 and the electrically conductive layer 102, e.g. a copper foil, of 1 μm to 10 μm thickness. The stack up is continued with a further electrically insulating layer 306 of a suitable prepreg, optionally followed by e.g. an adhesion promoter layer 111, and an electrically conductive layer 102, e.g. a copper foil. Alternatively, the stack up can be made without prepreg by coating a second layer of NIL photoresist as a further electrically insulating layer 306 and structuring the same.

The further layer structure 301 may be formed by the processes described in FIGS. 1A to 1H or in FIGS. 2A to 2J above.

In FIG. 3B, for the formation of the vias hole 310 a sacrificial electrically insulating layer 302, e.g. a curable NIL resist which is not permanently staying in the final build-up, is coated on the surface of the electrically conductive layer 102 with e.g. dispensing or spin coating. Next, the electrically conductive layer 102 is structured via e.g. LDI (Laser Direct Imaging) and developing of a photoresist, or via soft mold NIL stamping and UV curing. The via holes 310 (microvia openings) are formed in the electrically conductive layer 102 electrically conductive layer 102 after a resist film stripping and/or plasma etching process of the electrically conductive layer 102 is etched away in the via holes 310.

In FIG. 3C, the via holes 310 are etched into sacrificial electrically insulating layer 302 and further in the electrically conductive layer 102 via dry etching, e.g. via Reactive Ion Etching (RIE) or plasma process to access the further electrically conductive layer 305 below. The sacrificial electrically insulating layer 302, e.g. photoresist or NIL resist, is stripped off.

In FIG. 3D, after the RIE and e.g. a plasma supported step for cleaning the via hole 310, the etched microvia holes 310 in the prepreg can be optionally coated with an adhesion promoter layer 111. Then to manufacture an electric contact for the via filling process the via holes 310 may be coated with a seed layer of an electrically conductive material, e.g. an E-less copper chemistry or as alternative conductive carbon, conductive polymer or via Pd or Pd—Sn layer during direct metallization or sputtering.

In FIG. 3E, the imprint resist layer 104, e.g. a permanent curable NIL resist, is added onto the electrically conductive layer 102. In particular, the imprint resist layer 104 is selectively coated on the surface of the electrically conductive layer 102 with dispensing coating, wherein the imprint resist layer 104 is in particular selectively added to the electrically conductive layer 102 such that the via holes 310 are kept uncovered before stamping. The coated, electrically conductive microvia holes 310 that will be filled with electrically conductive material 202 (e.g. copper) in further a plating process remain uncoated from the permanent imprint resist layer 104. Next, the imprint resist layer structuring processes comprises roll-to-plate as well as step and repeat plate-to-plate NIL processes. To avoid the undesired filling of NIL resist material into the coated via holes 310 during the stamping process, the NIL stamp can comprise a pattern to block or close the via hole 310 during the NIL stamping process forms the recesses 105 comprising the bottom residue 106. The resist layer through holes 311 may be slightly larger than the via hole 310 in the electrically conductive layer 102. The oversize of the resist layer through holes 311 with respect to the diameter of the via hole 310 may be 1 μm, 2 μm or more. An alignment accuracy may be below 5 μm, preferred below 3 μm. This allows the manufacturing of small rest rings on the surface of the electrically conductive layer 102 uncovered by the imprint resist layer 104 smaller than 10 μm. Small rest rings are e.g. preferred for radar and high-frequency applications. Furthermore, also larger rings may be formed in order to form pads with a diameter of e.g. 3 μm to 200 μm.

The thickness of the permanent NIL imprint resist layer 104 can comprise 1 μm to 20 μm, preferred 1 μm to 10 μm. It can comprise known inorganic fillers as SiO₂, TiO₂, SiO₂—Al₂O₃ and/or glass. Suitable materials for permanent NIL photoresist imprint resist layer 104 may comprise SU 8 based epoxy negative resists, polyphenyl ether (PPE), polyimide or benzocyclobutene (BCB).

In FIG. 3F, after the structuring process via e.g. soft mold NIL stamping and UV curing and e.g. a further plasma supported step for cleaning the via hole 310, the empty microvias holes 310 are over-filled with electrically conductive material 202 (e.g. copper) to the same amount and more as the thickness of the electrically conductive layer 102 (e.g. the copper foil).

In FIG. 3G, after via over-filling (Cu) process, in the next step an (e.g. plasma) etching process is applied, to remove the bottom residue 106 in the recesses 105 of the imprint resist layer 104 and to provide access to the electrically conductive layer 102 below the recesses 105. Specifically, the bottom residue 106 may have a thickness of smaller than 100 nm. Then, a e.g. (Copper) microetching process is etching simultaneously the circuit pattern (i.e. the filling structure 108) in the electrically conductive layer 102 below the recesses 105 and at the same time, the excess plated electrically conductive material 202 (e.g. copper) on the top of the microvia 201 is etched as well. For example, a copper microetch process which may comprise UV light, etching additives as Iodine and polymers to improve the etching process may be used for this step.

In FIG. 3H, the permanent NIL imprint resist layer 104 remains in the stack up, and protects the etched, fine micro and sub-micrometer sized pattern filling structure 108. The stack-up is continued with the layup of a suitable further electrically insulating layer 307. The material of the further electrically insulating layer 307 is filled in the recesses 104 of the imprint resist layer 104 and the filling structures 108 of the electrically conductive layer 102. The stack up is continued with the further electrically insulating layer 109 of a suitable prepreg, followed by e.g. an adhesion promoter layer 111, and a further electrically conductive layer 110, e.g. a copper foil. Alternatively, the stack up can be made without prepreg by coating a second layer of NIL photoresist as a further electrically insulating layer 109 and structuring the same.

In FIG. 3I, after the stack-up has been completed the temporary carrier structure 103 is removed, such that the layer structure 101 for the component carrier 100 is formed. Hence, after the stack-up has been completed, the glass carrier 103 is released by support of UV light in order to release the release layer 112. Further, a bottom layer of the electrically conductive layer 102, e.g. the copper foil, on the bottom of a flat surface with (copper) microstructures and sub microstructures is removed by an etching process.

In FIG. 3J, on the bottom, finally a flat surface with copper via protrusion/pillar 206 forming pads is obtained with an alignment accuracy below 0.2 μm suitable for mounting a component 150 vie e.g. solder bumps 151. The further electrically insulating layer 109 at the top section may be structured and a further via 304 may be formed. Furthermore, the further electrically conductive layer 110 on top of the electrically insulating layer 109 may be structured such that a pad section 304 of the further electrically conductive layer 110 by be formed and electrically coupled to the further via 304.

Summarizing, the further imprint resist layer 303 may have a further stamped predefined structure and a further electrically conductive layer 305. The further imprint resist layer 303 is arranged onto the further electrically conductive layer 305. The further electrically conductive layer 305 and the further imprint resist layer 303 comprise at least one indentation forming a further via hole for forming a further via 304, wherein the at least one indentation and the further stamped predefined structure of the further imprint resist layer 303 are at least partially filled with electroplated metallic base structure 202′ and a further electroplated electroplating structure 203′. The layer structure 101 is arranged onto the further layer structure 301 such that the via 201 of the layer structure 101 is connected to the further via 304 in particular for forming a multi-layer redistribution structure or an interposer. The interposer translates a small pitch size into a larger pitch size. The interposer may comprise glass as dielectric layer, for example.

As can be seen in FIG. 3J, the further electrically conductive filling material 203′ forms part of a filling structure 108 which is a conductive path along a top surface of the further imprint resist layer 303 for connecting horizontally spaced vias 201, 304. Furthermore, a further via 313 may be formed in the further electrically insulating layer 109 for connecting a pad section 312 of the further electrically conductive layer 110 with the via 201 in the imprint resist layer 104.

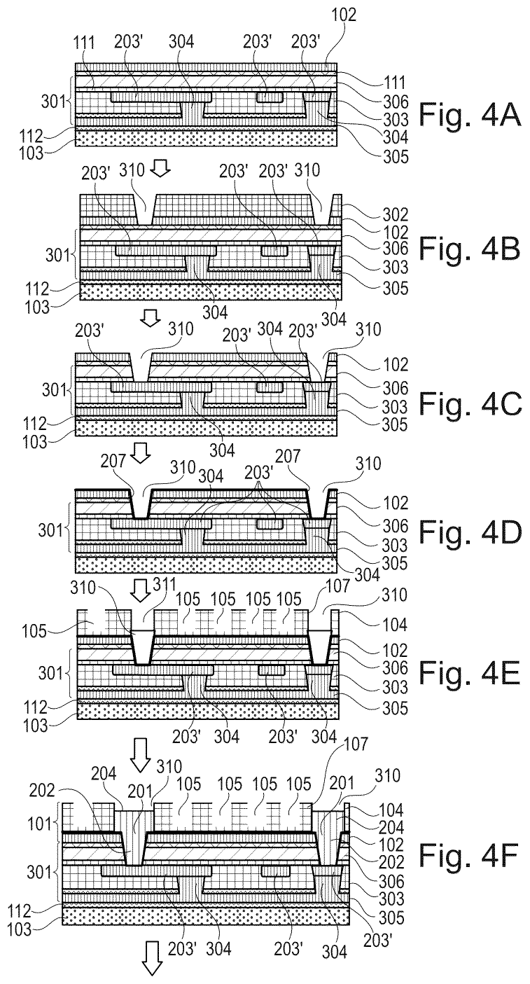

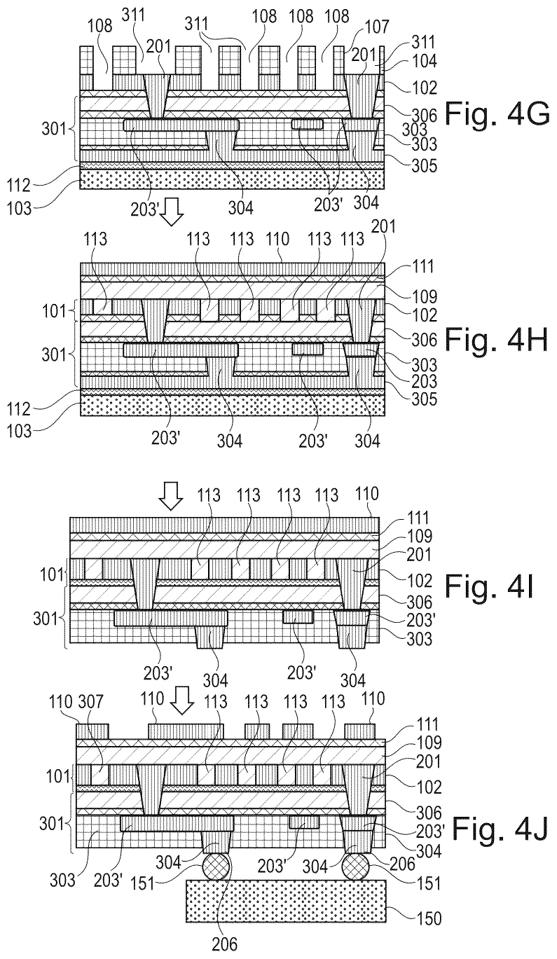

FIGS. 4A to 4J illustrate a schematic view of a method of manufacturing a component carrier 100 with a plurality of layer structures 101, 301 with a temporary sacrificial imprint resist layer 104, which will be removed, and a forming of a via 201 in an electrically conductive structure according to an exemplary embodiment.

In FIG. 4A, to build up the stack-up of a further layer structure 301, a further permanent electrically insulating layer 303, e.g. a prepreg or a further (NIL) imprint resist layer, and a further electrically conductive layer 305, such as a copper foil of 1 μm to 10 μm thickness are pressed on conductive (copper) structures, such as a further (copper) via 304. The further electrically conductive layer 305 is applied onto the temporary carrier structure 103, e.g. a glass carrier. The temporary carrier structure 103 is coated with a release layer 112 and the carrier layer which is in particular an electrically conductive layer 102, e.g. a copper foil, of 1 μm to 10 μm thickness. The stack up is continued with a further electrically insulating layer 306 of a suitable prepreg, followed by e.g. an adhesion promoter layer 111, and an electrically conductive layer 102, e.g. a copper foil. Alternatively, the stack up can be made without prepreg by coating a second layer of NIL photoresist as a further electrically insulating layer 306 and structuring the same.

The further layer structure 301 may be formed by the processes described in FIGS. 1A to 1H or in FIGS. 2A to 2J above.

In FIG. 4B, for the formation of the vias 201 a sacrificial electrically insulating layer 302, e.g. a photo resist or curable NIL imprint resist layer, is coated on the surface of the electrically conductive layer 102 with e.g. dispensing or spin coating. After the structuring process of the electrically conductive layer 102 via e.g. LDI (Laser Direct Imaging) and developing of a photoresist, or via soft mold NIL stamping and UV curing. The via holes 310 (microvia openings) are formed in the electrically conductive layer 102 after a resist film developing or plasma etching process of the electrically conductive layer 102 is etched away in the via holes 310.

In FIG. 4C, the via holes 310 are further etched in the permanent electrically insulating layer 306 and in the adhesion promoter layer 111 via dry etching, e.g. via Reactive Ion Etching (RIE) or plasma process to access the further electrically conductive layer 305 below. The sacrificial electrically insulating layer 302, e.g. photoresist or NIL resist, is stripped off.

In FIG. 4D, after the RIE and e.g. a plasma supported etching step and an optional plasma desmear step for cleaning the via hole 310, an electric contact for the via filling process the via holes 310 may be coated with an E-less Copper chemistry or as alternative conductive carbon, conductive polymer or via Pd or Pd—Sn layer during direct metallization. The wall of the etched via holes 310 may also be coated by a Titanium and or Copper sputtering process such that seed layer 207 is formed. Hence, an electro-less Copper process, conductive carbon, conductive polymer as PEDOT or polythiophene process or Pd layer via direct metallization is conducted for coating the via holes 310.

Alternatively, a bottom-up filling of the via further 310 connected to the bottom electrically conductive layer 102 can be provided, so that no seed layer 207 is necessary.

In FIG. 4E, a sacrificial imprint resist layer 104, e.g. a sacrificial UV NIL photoresist, is selectively deposited onto the electrically conductive layer 102. In particular, the imprint resist layer 104 is coated on the surface of the electrically conductive layer 102 with dispensing coating, wherein the imprint resist layer 104 is in particular added to the electrically conductive layer 102. Next, the imprint resist layer structuring processes comprises roll-to-plate as well as step and repeat plate-to-plate NIL processes. To avoid the undesired filling of NIL resist material into the coated via holes 310 during the stamping process, the NIL stamp can comprise a pattern to block or close the via hole 310 during the NIL stamping process which forms the recesses 105 comprising the bottom residue 106. The resist layer through holes 311 may be slightly larger than the via hole 310 in the electrically conductive layer 102. The oversize of the resist layer through holes 311 and hence the alignment accuracy is below 5 μm, preferred below 3 μm. This allows the manufacturing of small rest rings on the surface of the electrically conductive layer 102 uncovered by the imprint resist layer 104 smaller than 10 μm. Small rest rings are e.g. preferred for radar and high frequency applications.

The thickness of the permanent NIL imprint resist layer 104 can comprise 1 μm to 20 μm, preferred 1 μm to 10 μm. It can comprise known inorganic fillers as SiO₂, TiO₂, SiO₂—Al₂O₃ and/or glass. Preferred it is free of inorganic fillers and has a small shrinking factor. Suitable materials for permanent NIL photoresist imprint resist layer 104 may comprise SU 8 based epoxy negative resists.

In FIG. 4F, after the structuring process via e.g. soft mold NIL stamping and UV curing and e.g. a further plasma supported etching step for cleaning the via hole 310, the empty microvias holes 310 are over-filled with electrically conductive material 202 (e.g. copper) to the same amount and more as the thickness of the electrically conductive layer 102 (e.g. the copper foil).

In FIG. 4G, after via over-filling (Cu) process, in the next step a (e.g. plasma) etching process is applied, to remove the bottom residue 106 in the recesses 105 of the imprint resist layer 104 and to provide access to the electrically conductive layer 102 below the recesses 105. Then, a e.g. (Copper) microetching process is etching simultaneously the circuit pattern (i.e. the filling structure 108) in the electrically conductive layer 102 below the recesses 105 and at the same time, the excess plated electrically conductive material 202 (e.g. copper) on the top of the microvia 201 is etched as well. For example, copper microetch process which may comprise UV light, etching additives as Iodine and polymers to improve the etching process may be used for this step.

In FIG. 4H, the sacrificial NIL imprint resist layer 104 which remains is removed after the microetching of the micrometer patterns, i.e. the filling structures 108 from the surface e.g. via plasma etching. An electrically insulating material 113 is filled in the filling structures 108 (as shown in FIG. 4G) of the electrically conductive layer 102. The stack-up is continued with the further electrically insulating layer 109 of a suitable prepreg, followed by e.g. an adhesion promoter layer 111, and a further electrically conductive layer 110, e.g. a copper foil. Alternatively, the stack up can be made without prepreg by coating a second layer of NIL photoresist as a further electrically insulating layer 109 and structuring the same.

In FIG. 4I, after the stack-up has been completed the temporary carrier structure 103 is removed, such that the layer structure 101 for the component carrier 100 is formed. Hence, after the stack-up has been completed, the glass carrier 103 is released by support of UV light in order to release the release layer 112. Further, a bottom layer of the electrically conductive layer 102, e.g. the copper foil, on the bottom a flat surface with (copper) microstructures and sub microstructures is removed by an etching process.

In FIG. 4J, on the bottom, finally a flat surface with copper via protrusion/pillar 206 forming pads is obtained with an alignment accuracy below 0.2 μm suitable for mounting a component 150 vie e.g. solder bumps 151. The further electrically conductive layer 110 at the top section may also be structured.

Regarding the manufacturing methods shown in FIG. 3A to 3J and FIG. 4A to FIG. 4J, a further build up of a plurality of further layer structures 101 may be applied in order to provide a more multi layered component carrier 100. As described above, it is also possible to apply a surface finish selectively to exposed electrically conductive surface portions 110, 206 of the component carrier 100 in terms of surface treatment. Such a surface finish may be an electrically conductive cover material on exposed electrically conductive layer structures 110 (such as pads, conductive tracks, etc., in particular comprising or consisting of copper) on a surface of a component carrier 100. A surface finish may then be formed for instance as an interface between the surface mounted component 150 and the component carrier 110.

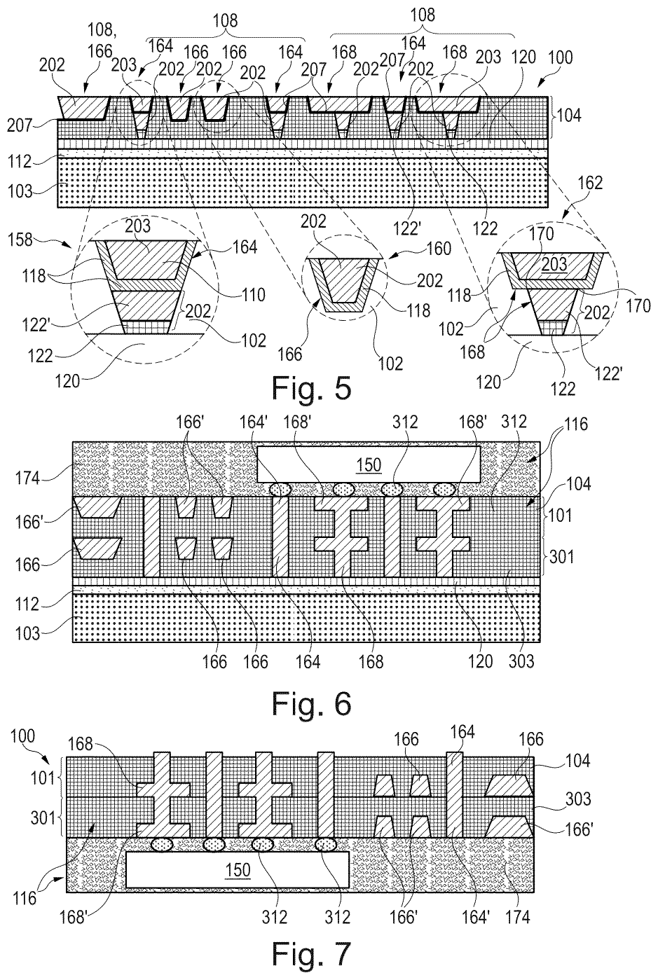

FIG. 5 shows a layer structure 101 having a plurality of filling structures 108 forming vias 201 in the imprint resist layer 104. In the filling structures 108 the further electrically conductive material 203 may protrude beyond the imprint resist layer 104. Electrically conductive wiring structures obtained as a result of the described manufacturing process are shown in a detail 158, in a detail 160 and in a detail 162 of FIG. 5, respectively.

As illustrated in detail 158, through hole-type wiring structures 164 extending completely through profiled imprint resist layer 104 have tapering sidewalls. A bottom portion of a respective wiring structure 164 is constituted by bottom-sided portion 122 of the electrically conductive material 202, wherein a top-sided portion 122′ of the electrically conductive material 202 is formed directly on the bottom-sided portion 122. A remaining volume of the wiring structure 164 is lined with seed layer 207 covering a top surface 122 of the electrically conductive material 202 as well as an exposed sidewall of the imprint resist layer 104. A remaining volume of the wiring structure 164 delimited by the seed layer 207 is filled with the (e.g. electroplated) further electrically conductive material 203.

As illustrated in detail 160, blind hole-type wiring structures 166 extending only partially through profiled imprint resist layer 104 have tapering sidewalls and a horizontal bottom surface. Both the latter mentioned tapering sidewalls as well as the horizontal bottom surface are lined with seed layer 207. A remaining volume of the wiring structure 166 delimited by the seed layer 207 is filled with the electrically conductive material 202.

As illustrated in detail 162, through hole-type wiring structures 168 (e.g. a via 201) extending completely through profiled imprint resist layer 104 have tapering sidewalls with a stepped profile, a corresponding step being indicated by reference sign 170. Wiring structures 168 correspond to wiring structures 164 with the difference that the wiring structures 168 have step 170 between portions of the tapering sidewalls and therefore form a hybrid of a via-type wiring structure in a bottom portion and a trace-type wiring structure in a top portion.

As shown, fully embedded electrically conductive structures can be obtained, both of a via-type (see wiring structures 164) and of a trace-type (compare wiring structures 166), as well as a combination of both (compare wiring structures 168). The structure shown in FIG. 5 can be used as a readily manufactured component carrier 100.

Highly advantageously, the filling structures 108 can be filled with two or more different metallic substructures (see reference signs 122, 122′, 202, 203) which may be made of two or more different metallic materials for fine-tuning the properties of the wiring structures 164, 166, 168. Alternatively, an entire wiring structure 164, 166, 168 may be filled with a single metallic material only, for example copper, with material interfaces in between.

FIG. 6 shows a component carrier 100 having a build up 116 of a layer structure 101 with an imprint resist layer 104 and a further layer structure 301 with a further imprint resist layer 303. A component 150 is surface mounted on the stacked imprint resist layers 104, 303 and can be electrically connected to any of the wiring structures 164′, 166′, 168′, 164, 166, 168, for example by soldering or other appropriate methods like thermal compression bonding. Soldering may be accompanied by solder structures 312 arranged between the stacked imprint resist layers 104, 303 on the one hand and the component 150 on the other hand. For example, component 150 may be a semiconductor die.

FIG. 7 shows the component 150 being surface mounted on and being electrically coupled with the stacked imprint resist layers 104, 303. The component 150 may then be overmolded by a mold compound 174.

As illustrated in FIG. 8 it is then possible to detach the stacked imprint resist layers 104, 303 with the integrated wiring structures 164, 166, 168, 164′, 166′, 168′ and with the surface mounted and overmolded component 150 from the temporary carrier structure 103 at the release layer 112. By taking this measure, the wiring structures 164, 166, 168 may be exposed so as to be connectable to an electronic periphery (not shown). In order to obtain the component carrier 100 according to FIG. 8, the surface mounted components 150 may be overmolded by a mold compound 174.

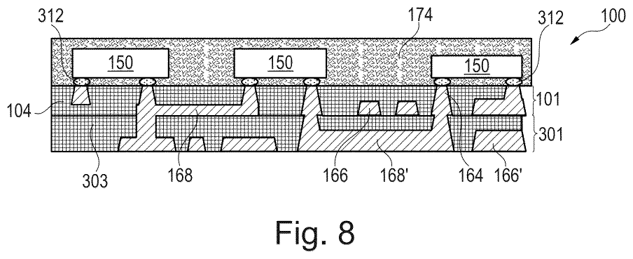

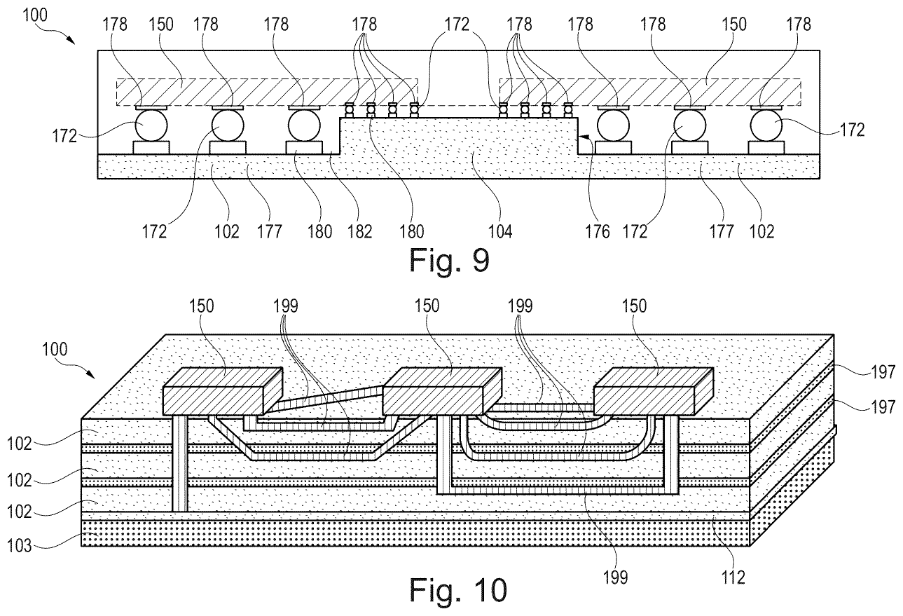

FIG. 9 illustrates a component carrier 100 according to still another exemplary embodiment of the disclosure. According to FIG. 9, two surface mounted components 150 (for example semiconductor chips) are arranged side-by-side on the imprint resist layers 104 and are electrically coupled with each other by electrically conductive connection structures 180 at a protrusion 176 of the imprint resist layer 104 and on the imprint resist layers 104 apart from the protrusion 176.

According to FIG. 9, the imprint resist layer 104 is also used for horizontally connecting the laterally juxtaposed components 150 which are surface mounted on the imprint resist layer 104 at the same vertical level. To accomplish this connection, the imprint resist layer 104 is equipped with central protrusion 176 protruding vertically beyond horizontal surface portions 177 of the stepped imprint resist layer 104. Bottom-sided pads 178 of the two components 150 are electrically connected with each other and with wiring structures of the imprint resist layer 104 by electrically conductive connection structures 180 on the protrusion 176 of imprint resist layer 102 and on imprint resist layer 104 apart from the protrusion 176. By the illustrated connection architecture, a conventionally used silicon bridge may become dispensable.

According to FIG. 9, each of the two components 150 comprises pads 178 having different pitch sizes (in particular having different diameters) and being electrically coupled with the electrically conductive connection structures 180 having different pitch sizes (in particular having different diameters) by connection structures which are here embodied as solder structures 172 having different dimensions. As shown, each of the components 150 may have pads 178 with different pitch sizes, i.e. a first group of pads 178 having a smaller diameter than a second group of pads 178. Larger pads 178 of a respective component 150 are coupled with larger connection structures 180 of the imprint resist layer 104 by larger solder structures 172, whereas smaller pads 178 of said component 150 are coupled with smaller connection structures 180 of the imprint resist layer 104 by smaller solder structures 172. With an NIL-based imprint resist layer 104, it is not only possible to realize pads 178 for those different sizes, but it may also be possible to create different heights, so that the areas having a larger pitch size (and thus are connected with larger solder balls) are on another vertical level than the tighter connection pads 178, i.e. having a smaller pitch size (and thus being connected by smaller solder balls).

In a further embodiment (not shown), at least one first pad of the pads 178 has a smaller pitch size than at least one second pad of the pads 178 having a larger pitch size, wherein the at least one first pad is electrically coupled with at least one first of the electrically conductive connection structures 180 on the imprint resist layer 104, and wherein the at least one second pad is electrically coupled with at least one second of the electrically conductive connection structures 180 on a laminated printed circuit board layer stack 131 apart from the imprint resist layer 104. Hence, only the area with tight connection pads 178 may be realized with an imprint resist layer 104 formed in NIL-technology, for example directly on a component carrier 100, or as a separate board which is then mounted on the component carrier 100.

It is also possible to form a wiring structure 182 which extends partially horizontally and partially vertically between the electrically conductive connection structures 180 on the protrusion 176 and apart from the protrusion 176 on the imprint resist layer 104.

The embodiment of FIG. 9 shows that the NIL-type imprint resist layer 104 may also function as a bridge or redistribution structure for one or more surface mounted components 150 of the component carrier 100. Hence, a NIL-type imprint resist layer 104 may also be configured for a fan-out function in a component carrier 100.

FIG. 10 illustrates a component carrier 100 according to yet another exemplary embodiment of the disclosure. In the exemplary embodiment, the filling structure 108 comprises three-dimensionally curved substructures. According to FIG. 10, the filling structure comprises three-dimensionally curved substructures indicated by reference sign 199. Such substructures may be formed, for instance also with undercut or the like, by the above-described principles for forming wiring structures 164, 166, 168 and by the combination of multiple stacked imprint resist layer 104. Optionally, adjacent imprint resist layers 104 may be mutually connected by optional connection layers 197.

For instance, the shown embodiment can be implemented in terms of a chip last 3D manufacturing architecture. With three-dimensionally stamped NIL imprint resist layer 104, any slope required for any structure may be designed. Advantageously, stamping may lead to very smooth surfaces with a roughness Ra of less than 100 nm, or even of not more than 50 nm. Plated copper structures may be formed with high crystallinity and substantially without porosity.

In embodiments, one or more NIL-type imprint resist layers 104 may be further treated by three-dimensionally printing. This may further extend the opportunities of NIL technology for manufacturing component carriers 100, such as printed circuit boards.

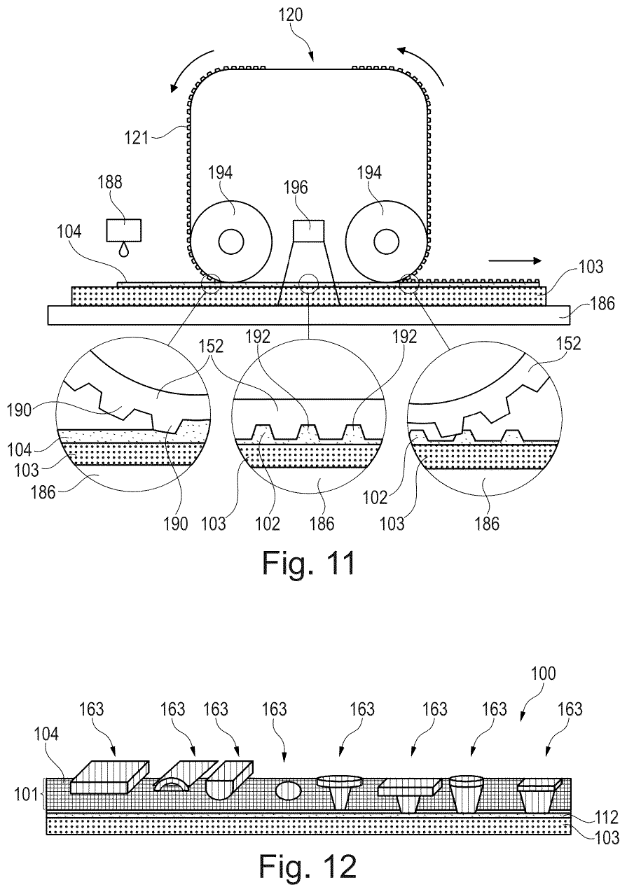

FIG. 11 shows a device 120 for stamping a surface profile in imprint resist layers 104 using a working mold 121 according to an exemplary embodiment.

As shown, a planar uncured imprint resist layer 104 may be formed on a temporary carrier structure 103 which may be transported along a support 186. Material of the imprint resist layer 104 may be applied to the imprint resist layer 104 from a reservoir 188. The working mold 121 may have a designable and preferably tapering surface profile 190 and may stamp an inverse and preferably tapering surface profile 192 in the imprint resist layer 104. For this purpose, the working mold 121 may for example rotate using rotating wheels 194 to thereby produce a continuous sheet with a stamped profiled imprint resist layer 104. By a light source 196 (such as a UV lamp), the imprint resist layer 104 may be cured during stamping.

FIG. 12 illustrates a component carrier 100 according to still another exemplary embodiment of the disclosure. In this embodiment, it is shown that a component carrier 100 with metal plated filled wiring structures 108 of one or more profiled imprint resist layers 104 can comprise straight or curved traces 163 of very different geometries. The illustrated possible shapes of the traces 163 are (from left to right) a cuboid shape, a convex or concave shape, a half cylindrical shape, a spherical shape, a T-shape (shown with two different aspect ratios), a combined cylindrical and frustoconical shape, and a combined rectangle and frustum shape. Creation of a huge plurality of other shapes is possible, in particular when a plurality of imprint resist layer 104 are stacked.

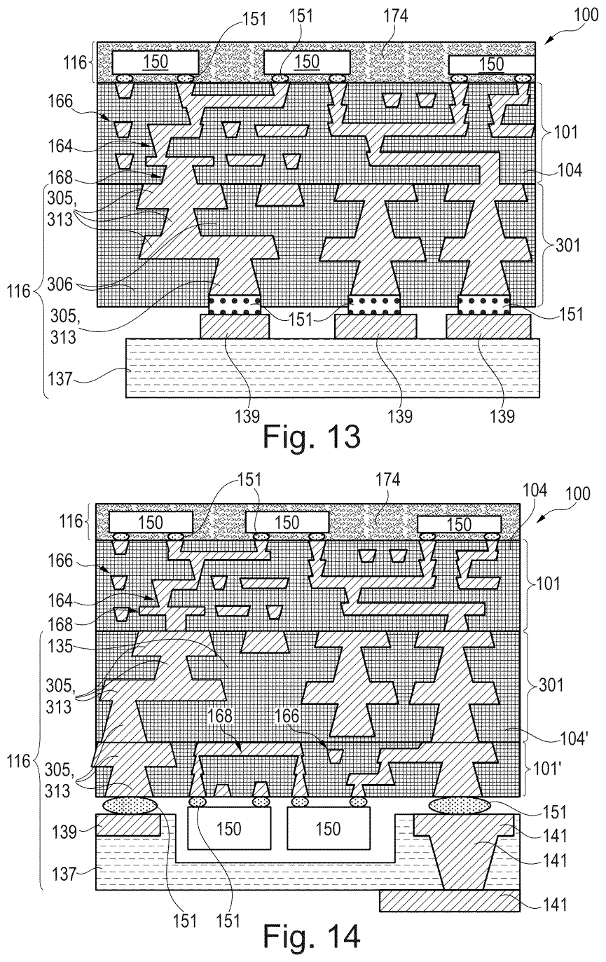

FIG. 13 illustrates a component carrier 100 according to yet another exemplary embodiment of the disclosure. In the shown embodiment, two build-ups 116, one of a layer structure 101 and one of a further layer structure 301, on both opposing main surfaces of respective stacked profiled imprint resist layers 104, 303 with integrated wiring structures (for example 164, 166, 168) are illustrated.

On a top side of imprint resist layer 104, a first build-up 116 is formed which is composed of components 150 being surface mounted and electrically connected to the stacked profiled imprint resist layer 104 by solder structures 151 and being encapsulated in a mold compound 174.

On a bottom side of said imprint resist layer 104, a second build-up 116 is formed which comprises a further layer structure 301, i.e. a laminated printed circuit board layer stack (which can be, for example, a PCB, an IC substrate or an interposer). The illustrated laminated printed circuit board layer stack may be composed of electrically conductive layer structures 305 and vertical through-connections, for example copper filled laser vias 313, and electrically insulating layer structures 306. For instance, the electrically insulating layer structures 306 may be parallel dielectric layers. For example, the electrically conductive layer structures 306 may comprise patterned copper foils (i.e. patterned metallic layers). The electrically insulating layer structures 306 may comprise a resin (such as epoxy resin), optionally comprising reinforcing particles therein (for instance glass fibers or glass spheres). For example, the electrically insulating layer structures 306 may be made of prepreg or FR4. The layer structures may be connected by lamination, i.e. the application of pressure and/or heat.

As shown, the integration density of wiring structures in said imprint resist layer 104 may be larger than in said laminated printed circuit board layer stack. On a bottom side of the further layer structure 301, a mounting base 137 (such as a motherboard) with electrically conductive connection pads 139 may be connected mechanically and electrically by solder structures 151.

Hence, FIG. 13 illustrates a hybrid package showing a PCB build-up (see reference sign 301) with NIL-layers (see reference sign 104) on one side. Components 150 may be provided on top and optionally also on bottom, together with solder structures 151 (for example solder balls) for mounting.

The metallized imprint resist layer 104 form an advanced polymer substrate comprising three fan-out redistribution layers with smaller line space ratio L/S (for instance in a range from 0.5 to 5 μm/0.5 to 5 μm) on top. A larger line space ratio L/S (for instance in a range from 2 to 40 μm/2 to 40 μm, or even larger) may be provided for the substrate in form of laminated printed circuit board layer stack 301 below.

For example, the solder structures 151 may be embodied as solder balls or galvanic plated solder pillars (for instance with the composition of 66 weight % Cu, 33 weight % Sn, and less than 3 weight % Ag).

FIG. 14 illustrates a component carrier 100 according to yet another exemplary embodiment of the disclosure. Also, in the embodiment of FIG. 14, two build-ups 116 are provided on both opposing main surfaces of upper stacked profiled imprint resist layers 104 of a layer structure 101 with integrated wiring structures (for example 164, 166, 168) are illustrated. On a top side of said upper imprint resist layer 104, a first build-up 116 is formed which may be embodied as in FIG. 13. On a bottom side of said upper imprint resist layer 104, a second build-up 116 is formed which comprises a laminated printed circuit board layer stack of a further layer structure 301, similar as in FIG. 13.

On a bottom side of the laminated printed circuit board layer stack, imprint resist layer 104′ of a further layer structure 101′ are arranged. On a bottom side of the lower imprint resist layer 104′, a mounting base 137 (such as a motherboard) with one or more electrically conductive connection pads 139 may be connected mechanically and electrically by solder structures 151. Furthermore, additional components 150 may be surface mounted on a lower side of the lower imprint resist layer 104′, for instance by solder structures 151. Additional electrically conductive layer structures 141 may be integrated in the mounting base 137. The solder structures 151 of FIG. 14 may be embodied as in FIG. 13. As shown, the integration density of wiring structures in each of said upper and lower layer structures 101, 101′ may be larger than in said laminated printed circuit board layer stack of the further layer structure 301.

Hence, FIG. 14 illustrates a hybrid package showing a PCB-type stack (see reference sign 301) with areas of NIL-layers (see reference signs 104, 104′) between which the PCB-type stack is arranged.

The upper metallized imprint resist layers 104 may form an advanced polymer substrate comprising three fan-out redistribution layers with smaller line space ratio L/S (for instance in a range from 0.5 to 5 μm/0.5 to 5 μm, or from 0.5 to 8 μm/0.5 to 8 μm) on top. A larger line space ratio L/S (for instance in a range from 5 to 15 μm/5 to 15 μm, or from 8 to 20 μm/8 to 20 μm) may be provided for the substrate in form of laminated printed circuit board layer stack of the further layer structure 301 below.

The electrically conductive layer structures 141 of the mounting base 137 may have a line space ratio L/S (for instance in a range from 50 to 200 μm/50 to 200 μm, or even larger) being larger than the line space ratio L/S of the laminated printed circuit board plastic of the further layer structure 301. The lower metallized imprint resist layers 104 may have a line space ratio L/S for instance in a range from 0.5 to 5 μm/0.5 to 5 μm, or from 0.5 to 8 μm/0.5 to 8 μm.

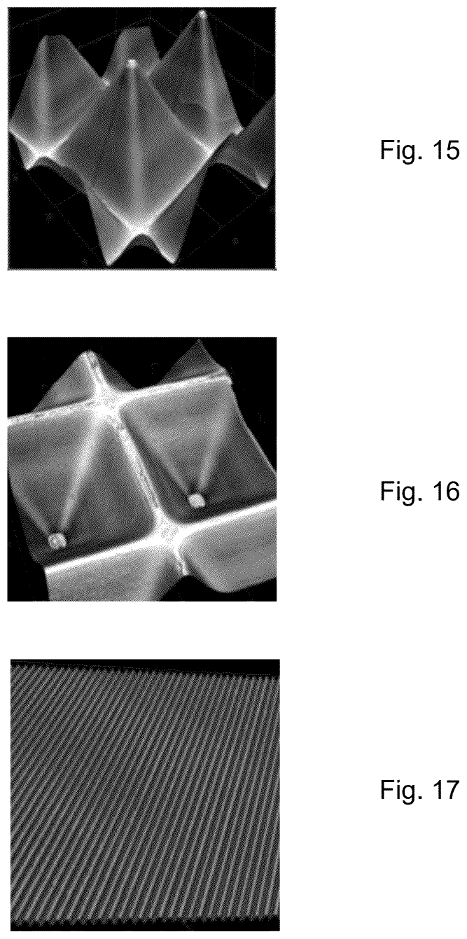

FIG. 15, FIG. 16, and FIG. 17 show three-dimensional views of stamped imprint resist layers used for manufacturing component carriers according to exemplary embodiments of the disclosure. Hence, FIG. 15 to FIG. 17 show samples of a NIL-process on panel level and illustrate the topography of the NIL-resist (i.e. the imprint resist layer 104) after stamping. While FIG. 15 and FIG. 16 refer to a height of 50 μm and a width of 150 μm, FIG. 17 relates to a height of 230 nm and a width of 400 nm.

A person skilled in the art will understand that the illustrated embodiments may omit certain features of component carriers for the sake of conciseness and for the sake of clarity. For example, further layers may be added, and finishing stages such as formation of a solder mask may be carried out although not described herein.

It should be noted that the term “comprising” does not exclude other elements or steps and the article “a” or “an” does not exclude a plurality. Also, elements described in association with different embodiments may be combined. Implementation of the disclosure is not limited to the preferred embodiments shown in the figures and described above. Instead, a multiplicity of variants is possible which variants use the solutions shown and the principle according to the disclosure even in the case of fundamentally different embodiments.

### REFERENCE NUMERALS

100 component carrier
101 layer structure
102 carrier layer, electrically conductive layer
103 temporary carrier structure
104 imprint resist layer
105 recess
106 bottom residue
107 protrusion
108 filling structure
109 further electrically insulating layer
110 further electrically conductive layer
111 adhesion promoter layer
112 release layer
113 electrically insulating material
116 build up
120 device for stamping
121 working mold
122 bottom sided portion of electrically conductive material
122′ top sided portion of electrically conductive material
131 printed circuit board layer stack
137 mounting base
139 electrically conductive connection pads
141 further electrically conductive layer
150 component
151 solder bump
158, 160, 162 detail view(s)
163 traces
164 via-type wiring structure
166 blind hole-type wiring structures
168 through hole-type wiring structure
170 step
172 solder structures
174 mold compound
176 protrusion
177 horizontal surface portion
178 both sided pads
180 conductive connection structures
182 wiring structure
186 support
188 reservoir
190 surface profile
192 tapering surface profile
194 wheel
196 light source
197 connection layer
201 via
202 electrically conductive material
203, 203′ further electrically conductive filling material, further electroplating structure
204 excess portion
205 excess electrically conductive material
206 via protrusion/pads
207 seed layer
301 further layer structure
302 sacrificial electrically insulating layer
303 permanent electrically insulating layer, further imprint resist layer
304 further via
305 further electrically conductive layer
306 further electrically insulating layer
307 further electrically insulating layer
310 via hole
311 resist layer through hole
312 solder structure, pad section
313 further via

1. A method of manufacturing a layer structure for a component carrier, the method comprising:
providing a carrier layer,
adding an imprint resist layer onto the carrier layer,
stamping predefined structures forming at least one recess into the imprint resist layer by a predefined stamp,
wherein the recess defines a filling structure in or on the carrier layer,
filling in the filling structure at least one of an electrically insulating material and an electrically conductive material.

2. The method according to claim 1, further comprising:
applying the carrier layer onto a temporary carrier structure, and
removing the temporary carrier structure after stamping the predefined structures, such that a layer structure for the component carrier is formed.

3. The method according to claim 1, comprising at least one of the following features:
further comprising
wherein the carrier layer is an electrically conductive layer;
further comprising
wherein the at least one recess comprises a bottom residue covering the electrically conductive layer;
further comprising
removing the bottom residue of the imprint resist layer in the recess by a subtractive removing process such that the respective recess provides access to the electrically conductive layer through the imprint resist layer;
further comprising after removing the bottom residue of the imprint resist layer in the recess
etching the electrically conductive layer in the regions accessible through the imprint resist layer such that respective filling structures are formed in the electrically conductive layer,
filling the filling structures in the electrically conductive layer with an electrically insulating material;
further comprising
after removing the bottom residue of the imprint resist layer in the recess
filling the filling structures with an electrically conductive material, and
forming a further conductive filling material onto the electrically conductive material in the via or in respective recesses to generate a conductive surface section;
wherein before forming the further conductive filling material coating the imprint resist layer or the via by a seed layer for forming of the further conductive filling material;
wherein the electrically conductive layer comprises copper wherein the electrically conductive layer (102) is in particular a copper foil comprising a thickness of 1 μm to 10 μm,
wherein the imprint resist layer comprises a thickness of 0.1 μm to 50 μm, wherein the imprint resist layer comprises in particular electromagnetic radiation curable material or a heat curable material,
wherein the imprint resist layer comprises in particular at least one of silicon dioxide, titanium dioxide, SiO₂—Al₂O₃, glass compounds and nanofillers;
wherein the imprint resist layer is added to the electrically conductive layer by coating;
wherein the predefined structures in the imprint resist layer are stamped by roll-to-plate process or a plate-to-plate process;
wherein the filling structures in the electrically conductive layer are spaced apart from each other with a distance less than 25 μm,
wherein an aspect ratio width/height of the filling structures is below a ratio of 1;
wherein the subtractive removing process for removing the bottom residue in the recess is a wet etching process or a dry etching process, or a plasma supported process.

4.-14. (canceled)

15. The method according to claim 1, comprising one of the following features:
wherein the filling structures comprises at least one of a through hole, blind holes and trenches formed in the carrier layer and or in the imprint resist layer; or
wherein filling structures are coated with an adhesion promoter layer for improving the binding to the electrically insulating material or the electrically conductive material in the subsequent filling step,
wherein filling structures are coated with barrier layer for to preventing ion migration,
wherein the adhesion promoter layer comprises at least one of Silanes and Siloxanes, quaternary ammonium polymer and their compositions,
wherein the barrier layer comprises at least one of Siloxanes, Silicon Nitride and their compositions and metals as Tin, Zinc, Nickel or Aluminum, Copper and their mixtures or alloys.

16. (canceled)

17. The method according to claim 1, comprising at least one of the following features:
further comprising
removing the imprint resist layer subsequent to the etching of the carrier layer, in such that a surface of the electrically conductive layer is uncovered, and
forming in particular a further electrically insulating layer onto the uncovered electrically conductive structure;
forming a further electrically conductive layer onto the further electrically insulating layer.

18. (canceled)

19. The method according to claim 1, comprising at least one of the following features:
wherein in the carrier layer at least one via hole is formed before the imprint resist layer is added to the electrically conductive layer;
wherein the imprint resist layer is aligned with the electrically conductive layer such that the via hole of the electrically conductive layer matches with the resist layer through hole;
wherein electrically conductive material is filled for forming a via in the via hole of the electrically conductive layer and the resist layer through hole such that an excess portion of the electrically conductive material is provided;
wherein, in or after the step of removing the bottom residue of the imprint resist layer, the excess portion in the resist layer through hole of the imprint resist layer is removed;
further comprising
forming a further electrically insulating layer, onto the imprint insulating layer,
wherein the recess of the imprint resist layer is filled with a material identical to the further electrically insulating layer or by a material different to the further electrically insulating layer;
further comprising
removing the imprint resist layer,
forming a further electrically insulating layer, onto the carrier layer,
wherein the filling structures in the electrically conductive layer are filled, with electrically insulating material identical to the further electrically insulating layer or by a material different to the further electrically insulating layer.

20.-23. (canceled)

24. The method according to claim 2,
wherein after removing the temporary carrier structure, the electrically conductive layer comprises noncovered electrically conductive pads to which a component is contactable.

25. The method according to claim 1,
applying the carrier layer, onto a further layer structure.

26. A component carrier, comprising:
at least one layer structure comprising at least one carrier layer,
wherein the at least one layer structure comprises an imprint resist layer,
wherein the imprint resist layer comprises predefined stamped structures,
wherein the predefined stamped structures being in contact with the at last one carrier layer,
wherein the predefined stamped structures comprise at least one recess defining a filling structure in or on the carrier layer, in which a filling structure is filled by at least one of an electrically insulating material or an electrically conductive material.

27. The component carrier according to claim 26,
wherein the filling structures are of different depth or different length in the imprint resist layer or the carrier layer.

28. The component carrier according to claim 26, comprising one of the following features:
wherein the carrier layer is an electrically conductive layer,
wherein the filling structure forms electrically insulated patterns in the electrically conductive layer for defining borders of electrically conductive traces formed by the electrically conductive layer; or
wherein the filling structure forms electrically conductive trace-type or a via hole forming a via and a via-type sub-structures, respectively.

29. (canceled)

30. The component carrier according to claim 26, comprising at least one of the following features:
wherein the filling structure forms at least one electrically conductive sub-structure having a depth-to-diameter ratio of larger than 1;
wherein the at least one recess forming part of the filling structure comprises tapering sidewalls;
wherein a roughness Ra of a surface of the imprint resist layer delimiting the surface profile is not more than 100 nm;
wherein the at least on recess forms a through hole so that at least one surface portion of the electrically conductive layer is exposed at the recess;
wherein a further conductive filling material is formed onto the electrically conductive material filled in the respective recess forming the filling structure;
further comprising
an electrically conductive seed layer selectively lining the filling structure of the imprint resist layer;
wherein at least one of the electrically conductive material and the further conductive filling material are plated layers,
wherein the electrically conductive material and the further conductive filling material are connected in a landless way.

31.-36. (canceled)

37. The component carrier according to claim 26, comprising at least one of the following features:
further comprising
a further layer structure onto which the layer structure is formed,
wherein the further layer structure comprises in particular at least one laminated printed circuit board layer stack;
wherein the further layer structure comprises a further imprint resist layer having a further stamped predefined structure and a further electrically conductive layer, wherein the further imprint resist layer is arranged onto the further electrically conductive layer,
wherein the further electrically conductive layer and the further imprint resist layer comprise at least one indentation forming a further via hole for forming a further via,
wherein the at least one indentation and the further stamped predefined structure of the further imprint resist layer are at least partially filled with electroplated metallic base structure, and a further electroplated electroplating structure;
wherein the layer structure is arranged onto the further layer structure such that the via of the layer structure is connected to the further via;
further comprising
a component mounted on imprint resist layer by a connection structure, arranged between the component and the imprint resist layer;
further comprising
two components arranged side-by-side at least partially on the imprint resist layer and being electrically coupled with each other by electrically conductive connection structures at or lateral from the imprint resist layer;
wherein at least one of the two components comprises pads having different pitch sizes being electrically coupled with the electrically conductive connection structures having different pitch sizes by connection structures having different dimensions;
wherein at least one first pad of the pads has a smaller pitch size than at least one second pad of the pads having a larger pitch size;
wherein the at least one first pad is electrically coupled with at least one first of the electrically conductive connection structures on the imprint resist layers; and
wherein the at least one second pad is electrically coupled with at least one second of the electrically conductive connection structures on a laminated printed circuit board layer stack apart from the imprint resist layers;
wherein the filling structure comprises three-dimensionally curved substructures;
wherein the filling structures of the stamped imprint resist layer are at least partially filled with at least one wiring structure of the group consisting of: a wiring structure having a bottom portion constituted by a bottom-sided portion of the electrically conductive material, wherein a top-sided portion of the electrically conductive material is formed directly on the bottom-sided portion, wherein a remaining volume of the wiring structure is lined with a portion of a seed layer covering a top surface of the electrically conductive material as well as an exposed sidewall of the imprint resist layer, and wherein a remaining volume of the wiring structure delimited by the portion of the seed layer is filled with at least a portion of a further electrically conductive material;
a wiring structure having a portion of a seed layer lining exposed sidewalls and an exposed bottom surface of the imprint resist layer, wherein a remaining volume of the wiring structure is filled with at least a portion of the further electrically conductive material;
a wiring structure having a bottom portion constituted by a bottom-sided portion of the electrically conductive material, wherein a top-sided portion of the electrically conductive material is formed directly on the bottom-sided portion, wherein a remaining volume of the wiring structure is lined with a portion of a seed layer covering a top surface of the electrically conductive material as well as an exposed sidewall and an exposed horizontal wall of the imprint resist layer, wherein a remaining volume of the wiring structure delimited by the portion of the seed layer is filled with at least a portion of the further electrically conductive material, and wherein the assigned filling structure has a step;
wherein at least a portion of the via protrudes beyond the imprint resist layer and thereby forms at least one via protrusion for electric connection with an electronic periphery;
wherein the imprint resist layer comprises an electrically insulating material;
wherein the imprint resist layer comprises an adhesion of more than 600 N/m;
wherein the imprint resist layer comprises temperature resistance between 200° C. and 300° C.;
wherein the imprint resist layer comprises material of a flame retardancy class 4;
wherein the imprint resist layer comprises material having a glass-transition temperature between 120° C. and 200° C.;
wherein the imprint resist layer has a Modulus below a glass-transition temperature of 1000 MPa to 14000 MPa;
wherein the imprint resist layer has a Modulus above a glass-transition temperature of 60 MPa to 800.

38.-53. (canceled)

54. The component carrier according to claim 26, comprising one of the following features:
wherein the imprint resist layer has a thermal expansion coefficient below a glass-transition temperature of 10 ppm/K to 40 ppm/K; or wherein the imprint resist layer has a thermal expansion coefficient above a glass-transition temperature of 50 ppm/K to 100 ppm/K.

55. (canceled)

56. The component carrier according to claim 26, comprising at least one of the following features:
wherein the imprint resist layer is formed with at least one of the following properties:
a fracture strain below a glass-transition temperature of is at least 2%,
a chemical shrinkage below 3%,
a moisture absorption below 0.1%, and
a desmear rate of more than 0.006 g/min;
wherein the imprint resist layer comprises a fully cured polymer based on at least one of the following group comprising epoxies, acrylates, polyphenylenether, polyimide, polyamide, polyetheretherketon poly (p-phenylene ether) (PPE), Bisbenzocyclobutene (BCB), or Polybenzoxabenzole (PBO).

57. (canceled)

58. The component carrier according to claim 26, comprising at least one of the following features:
wherein the imprint resist layer comprises polymer- or oligomer-based building blocks,
wherein at least one of the building blocks is based on one of the above-mentioned polymers;
wherein at least one of the building-blocks has at least one functional group covalently bond to another one of the least one building block;
wherein the at least one functional group is selected from one of the group comprising
a thiol group selected from the group of 3-mercaptopropionates, 3-mercaptoacetates, thioglycolates and alkylthiols, or
a double bond selected from the group of acrylates, methyl acrylates, vinyl ethers, allyl ethers, propenyl ethers, alkenes, dienes, unsaturated esters and allyl triazines, allyl isocyanates and N-vinyl amides

59.-60. (canceled)

61. The component carrier according to claim 26, wherein the imprint resist layer comprises a prepolymer having at least one photoinitiator, contained in an amount of 0.1 wt. % to 10 wt. %.

62. The component carrier (100) according to claim 26, comprising at least one of the following features:
wherein the imprint resist layer is in particular a fully cured resin,
wherein the imprint resist layer further comprises filler particles such as in an amount of 1 wt. % to 10 wt. %, in particular 1 wt. % to 3 wt. %;
wherein the chloride content of the resin is below 30 ppm;
wherein the filler particles comprise inorganic fillers;
wherein the inorganic fillers are in a crystalline state;
wherein the filler particles comprise a size of less than 0.1 μm.

63.-65. (canceled)

66. The component carrier (100) according to claim 61, comprising at least one of the following features:
wherein the filler particles comprise Talcum, Zeolite or fused SiO₂;
wherein the filler particles are of plasma etchable material;
wherein the imprint resist layer comprises less than 95% filler particles.

67.-68. (canceled)

69. The component carrier according to claim 26,
wherein the imprint resist layer comprises a viscosity of 0.01 Pas to 1 Pas.
